(19) United States
(12) Patent Application Publication
(10) Pub. No.: US 2025/0116922 A1
(43) Pub. Date: Apr. 10, 2025

(54) RADIATION-SENSITIVE RESIN COMPOSITION AND METHOD OF FORMING RESIST PATTERN

(71) Applicant: JSR CORPORATION, Tokyo (JP)

(72) Inventors: Takuya OMIYA, Tokyo (JP); Katsuaki NISHIKORI, Tokyo (JP); Kazuya KIRIYAMA, Tokyo (JP); Yuushi MATSUMURA, Tokyo (JP); Nozomi TERADA, Tokyo (JP)

(73) Assignee: JSR CORPORATION, Tokyo (JP)

(21) Appl. No.: 18/985,206

(22) Filed: Dec. 18, 2024

Related U.S. Application Data
(63) Continuation of application No. PCT/JP2023/013354, filed on Mar. 30, 2023.

(30) Foreign Application Priority Data
Jun. 22, 2022 (JP) 2022-100218

(51) Int. Cl. G03F 7/004; C08F 2/50; C08F 20/10

(52) U.S. Cl. CPC G03F 7/004; C08F 2/50; C08F 20/10

(57) ABSTRACT

A radiation-sensitive resin composition includes a polymer, solubility of which in a developer solution is capable of being altered by an action of an acid, and which has a first structural unit represented by the following formula (1); a radiation-sensitive acid generating agent; and an acid diffusion control agent having a monovalent radiation-sensitive onium cation and a monovalent organic acid anion.

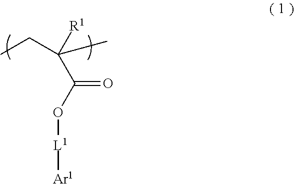

### CROSS-REFERENCE TO RELATED APPLICATIONS

The present application is a continuation application of International Patent Application No. PCT/JP2023/013354 filed Mar. 30, 2023, which claims priority to Japanese Patent Application No. 2022-100218 filed Jun. 22, 2022. The contents of these applications are incorporated herein by reference in their entirety.

### BACKGROUND OF THE DISCLOSURE

### Technical Field

The present disclosure relates to a radiation-sensitive resin composition and a method of forming a resist pattern.

### Background Art

A radiation-sensitive resin composition for use in microfabrication by lithography generates an acid at light-exposed regions upon an irradiation with a radioactive ray, e.g., an electromagnetic wave such as a far ultraviolet ray such as an ArF excimer laser beam (wavelength of 193 nm), a KrF excimer laser beam (wavelength of 248 nm), etc. or an extreme ultraviolet ray (EUV) (wavelength of 13.5 nm), or a charged particle ray such as an electron beam. A chemical reaction in which the acid serves as a catalyst causes a difference between the light-exposed regions and light-unexposed regions in rates of dissolution in a developer solution, whereby a resist pattern is formed on a substrate.

Such a radiation-sensitive resin composition is required not only to have favorable sensitivity to exposure light such as an extreme ultraviolet ray and an electron beam, but also to have superiority in terms of LWR (Line Width Roughness) performance and the like. In addition, along with further miniaturization of resist patterns, slight fluctuations in exposure and development conditions have come to exert an increasingly larger effect on configurations and generation of defects of resist patterns. Thus, a radiation-sensitive resin composition with a broad process window (a high process latitude) which enables absorption of such slight fluctuations in process conditions is also required.

Types, molecular structures, and the like of polymers, acid generating agents, and other components which may be used in radiation-sensitive resin compositions have been investigated to meet these requirements, and combinations thereof have been further investigated in detail (see Japanese Unexamined Patent Applications, Publication Nos. 2010-134279, 2014-224984, and 2016-047815).

### SUMMARY

According to an aspect of the present disclosure, a radiation-sensitive resin composition includes: a polymer, solubility of which in a developer solution is capable of being altered by an action of an acid, and which includes a first structural unit represented by formula (1); a radiation-sensitive acid generating agent; and an acid diffusion control agent comprising a monovalent radiation-sensitive onium cation and a monovalent organic acid anion.

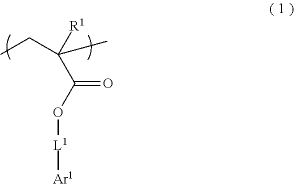

In the formula (1), R¹ represents a hydrogen atom, a fluorine atom, a methyl group, or a trifluoromethyl group; L¹ represents a single bond or a divalent linking group; and Ar¹ represents a group obtained by removing one hydrogen atom from a substituted or unsubstituted condensed polycyclic aromatic hydrocarbon ring having 13 or more ring atoms.

According to another aspect of the present disclosure, a method of forming a resist pattern, includes: applying the above-described radiation-sensitive resin composition directly or indirectly on a substrate to form a resist film; exposing the resist film; and developing the resist film exposed.

### DESCRIPTION OF THE EMBODIMENTS

Along with further miniaturization of resist patterns, required levels for the above-described performance are further elevated, and thus a radiation-sensitive resin composition that satisfies these requirements are demanded.

According to one aspect of the disclosure, a radiation-sensitive resin composition contains: a polymer (hereinafter, may be also referred to as “(A) polymer” or “polymer (A)”), solubility of which in a developer solution is capable of being altered by an action of an acid, and which has a first structural unit represented by the following formula (1); a radiation-sensitive acid generating agent (hereinafter, may be also referred to as “(B) acid generating agent” or “acid generating agent (B)”); and an acid diffusion control agent (hereinafter, may be also referred to as “(C) acid diffusion control agent” or “acid diffusion control agent (C)”) having a monovalent radiation-sensitive onium cation and a monovalent organic acid anion.

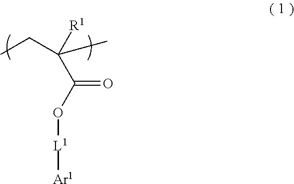

In the formula (1), R¹ represents a hydrogen atom, a fluorine atom, a methyl group, or a trifluoromethyl group; L¹ represents a single bond or a divalent linking group; and Ar¹ represents a group obtained by removing one hydrogen atom from a substituted or unsubstituted condensed polycyclic aromatic hydrocarbon ring having 13 or more ring atoms.

According to another aspect of the disclosure, a method of forming a resist pattern includes: applying the radiation-sensitive resin composition of the one aspect of the disclosure directly or indirectly on a substrate; exposing a resist film formed by the applying; and developing the resist film exposed.

The radiation-sensitive resin composition of the one aspect of the disclosure is superior in sensitivity and LWR performance, and is accompanied by a broad process window. The method of forming a resist pattern of the another aspect of the present disclosure enables forming a resist pattern which is superior in sensitivity and LWR performance, and is accompanied by a broad process window. Therefore, these can be suitably used for working processes of semiconductor devices, and the like, in which microfabrication is expected to be further in progress hereafter.

As used herein, the words “a” and “an” and the like carry the meaning of “one or more.” When an amount, concentration, or other value or parameter is given as a range, and/or its description includes a list of upper and lower values, this is to be understood as specifically disclosing all integers and fractions within the given range, and all ranges formed from any pair of any upper and lower values, regardless of whether subranges are separately disclosed. Where a range of numerical values is recited herein, unless otherwise stated, the range is intended to include the endpoints thereof, as well as all integers and fractions within the range. As an example, a stated range of 1-10 fully describes and includes the independent subrange 3.4-7.2 as does the following list of values: 1, 4, 6, 10.

Hereinafter, the radiation-sensitive resin composition and the method of forming a resist pattern according to the embodiments of the present disclosure will be described in detail.

### Radiation-Sensitive Resin Composition

The radiation-sensitive resin composition of the one embodiment of the present disclosure contains the polymer (A), the acid generating agent (B), and the acid diffusion control agent (C). The radiation-sensitive resin composition typically contains an organic solvent (hereinafter, may be also referred to as “(D) organic solvent” or “organic solvent (D)”). The radiation-sensitive resin composition may contain, within a range not leading to impairment of the effects of the present invention, other optional component(s).

The radiation-sensitive resin composition has effects that sensitivity and LWR performance are superior, and a process window is broad, due to the polymer (A), the acid generating agent (B), and the acid diffusion control agent (C) being contained. Although not necessarily clarified and without wishing to be bound by any theory, the reason for achieving the aforementioned effects by the radiation-sensitive resin composition due to involving such a constitution may be presumed, for example, as in the following. It is believed that the polymer (A) having the first structural unit represented by the following formula (1) results in an increase in the amount of the acid generated from the acid generating agent (B) and/or the like upon exposure. Then, due to the increase in the amount of the acid generated from the acid generating agent (B) and/or the like, the amount of alteration of solubility in the developer solution by the action of the acid contained in the polymer (A) is believed to increase. It is considered that as a result, the above-described effects are exhibited.

The radiation-sensitive resin composition may be prepared, for example, by: mixing, in a certain ratio, the polymer (A), the acid generating agent (B), and the acid diffusion control agent (C), as well as the organic solvent (D) and the other optional component(s), and the like, which are added as needed; and preferably filtering a thus resulting mixture through a membrane filter having a pore size of no greater than 0.20 μm.

Each component contained in the radiation-sensitive resin composition is described below.

### (A) Polymer

The polymer (A) has the first structural unit (hereinafter, may be also referred to as “structural unit (I)”) represented by the following formula (1). The polymer (A) is a polymer, solubility of which in a developer solution is capable of being altered by an action of an acid. The radiation-sensitive resin composition may contain, one or two or more types of the polymer (A).

The polymer (A) preferably further has a second structural unit (hereinafter, may be also referred to as “structural unit (II)”) that includes an acid-labile group. The polymer (A) preferably further has a third structural unit (hereinafter, may be also referred to as “structural unit (III)”) that includes a phenolic hydroxyl group. The polymer (A) may further have other structural unit(s) (hereinafter, may be also referred to as merely “other structural unit(s)”) aside from the structural units (I) to (III). The polymer (A) can have one, or two or more types of each structural unit.

It is to be noted that there may be a case in which the structural unit included in the polymer (A) is considered to fall under two or more categories of the structural unit, being overlapped. For example, a structural unit which is considered to fall under not only a category of structural unit (I), but also a category of one of the structural units other than the structural unit (I) can be included. In such a case, as referred to herein, the structural unit is defined to fall under the category of the structural unit denoted by the smaller number in parentheses.

The lower limit of a proportion of the polymer (A) in the radiation-sensitive resin composition with respect to total components other than the organic solvent (D) contained in the radiation-sensitive resin composition is preferably 50% by mass, more preferably 70% by mass, and still more preferably 80% by mass. The upper limit of the proportion is preferably 99% by mass, and more preferably 95% by mass.

The lower limit of a polystyrene-equivalent weight average molecular weight (Mw) of the polymer (A) as determined by gel permeation chromatography (GPC) is preferably 1,000, more preferably 2,000, still more preferably 3,000, and even further preferably 4,000. The upper limit of the Mw is preferably 30,000, more preferably 20,000, still more preferably 19,000, and even further preferably 17,000. When the Mw of the polymer (A) falls within the above range, coating characteristics of the radiation-sensitive resin composition may be improved. The Mw of the polymer (A) can be adjusted by, for example, regulating the type, the amount, and the like of a polymerization initiator used in synthesis of the same.

The upper limit of a ratio (hereinafter may be also referred to as “Mw/Mn” or “polydispersity index”) of the Mw to a polystyrene-equivalent number average molecular weight (Mn) of the polymer (A) as determined by GPC is preferably 2.5, more preferably 2.0, still more preferably 1.9, and even further preferably 1.7. The lower limit of the ratio is typically 1.0, preferably 1.1, more preferably 1.2, still more preferably 1.3, and even further preferably 1.4.

### Method for Measuring Mw and Mn

As referred to herein, the Mw and Mn of the polymer (A) are values measured by using gel permeation chromatography (GPC) under the following conditions.
GPC columns: “G2000 HXL”×2, “G3000 HXL”×1, and “G4000 HXL”×1, each available from Tosoh Corporation
column temperature: 40° C.
elution solvent: tetrahydrofuran
flow rate: 1.0 mL/min
sample concentration: 1.0% by mass
amount of injected sample: 100 uL
detector: differential refractometer
standard substance: mono-dispersed polystyrene

The polymer (A) can be synthesized by, for example, polymerizing a monomer that gives each structural unit in accordance with a well-known procedure.

Each structural unit included in the polymer (A) is described below.

### Structural Unit (I)

The structural unit (I) is a structural unit represented by the following formula (1).

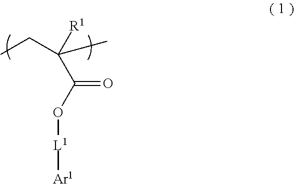

In the above formula (1), R¹ represents a hydrogen atom, a fluorine atom, a methyl group, or a trifluoromethyl group; L¹ represents a single bond or a divalent linking group; and Ar¹ represents a group obtained by removing one hydrogen atom from a substituted or unsubstituted condensed polycyclic aromatic hydrocarbon ring having 13 or more ring atoms.

The number of “ring atoms” as referred to herein means the number of atoms constituting a ring structure, and in the case of a polycyclic ring, the number of “ring atoms” means the number of atoms constituting the polycyclic ring. A “fused polycyclic ring” as referred to means a ring structure in which two adjacent rings have two shared atoms. The “fused polycyclic ring” is clearly distinguished from a “ring-assembled polycyclic ring” in which two adjacent rings are connected by a single bond without having any shared atom. A “group obtained by removing X hydrogen atom(s) from a ring structure” as referred to means a group obtained by removing X hydrogen atom(s) bonding to atom(s) constituting the ring structure.

R¹ represents, in light of a degree of copolymerization of the monomer that gives the structural unit (I), preferably a hydrogen atom or a methyl group, and more preferably a methyl group.

The divalent linking group which may be represented by L¹ is exemplified by a carbonyl group, an ether group, a sulfide group, an alkanediyl group having 1 to 10 carbon atoms, or a group obtained by combining the same, and the like. In the case in which L¹ represents the divalent linking group, the lower limit of the number of atoms of the chain between Ar¹ and the oxygen atom to which L¹ bonds is preferably 1 to 4.

L¹ represents, in light of more broadening of the process window of the radiation-sensitive resin composition, preferably a single bond. Furthermore, in light of more enhancing the sensitivity of the radiation-sensitive resin composition, the divalent linking group is preferred.

Examples of the condensed polycyclic aromatic hydrocarbon ring having 13 or more ring atoms that gives Ar¹ include: condensed tricyclic aromatic hydrocarbon rings such as an anthracene ring (ring atoms: 14), a phenanthrene ring (ring atoms: 14), and a phenalene ring (ring atoms: 13); condensed tetracyclic aromatic hydrocarbon rings such as a pyrene ring (ring atoms: 16), a chrysene ring (ring atoms: 18), a tetraphene ring (ring atoms: 18), a tetracene ring (ring atoms: 18), and a triphenylene ring (ring atoms: 18); condensed pentacyclic aromatic hydrocarbon rings such as a perylene ring (ring atoms: 20), a picene ring (ring atoms: 22), a pentaphene ring (ring atoms: 22), and a pentacene ring (ring atoms: 22); and the like.

The lower limit of ring atoms of the condensed polycyclic aromatic hydrocarbon ring may be 13, and is preferably 14. The upper limit of the ring atoms is preferably 22, more preferably 20, still more preferably 18, and even further preferably 16.

The condensed polycyclic aromatic hydrocarbon ring is preferably the condensed tricyclic aromatic hydrocarbon ring or the condensed tetracyclic aromatic hydrocarbon ring, more preferably an anthracene ring, a phenanthrene ring, or a pyrene ring, still more preferably an anthracene ring or a pyrene ring, and even further preferably a pyrene ring. Due to the sensitivity, the LWR performance, and the process window of the radiation-sensitive resin composition becoming further superior, the case of being an anthracene ring or a pyrene ring is preferred than the case of being a phenanthrene ring. Moreover, due to the sensitivity and the process window of the radiation-sensitive resin composition becoming even further superior, the case of being a pyrene ring is preferred than the case of being an anthracene ring.

Examples of a substituent which may be included in the condensed polycyclic aromatic hydrocarbon ring include halogen atoms such as a fluorine atom, a chlorine atom, a bromine atom, and an iodine atom, a hydroxy group, a carboxy group, a cyano group, a nitro group, an alkyl group, an alkoxy group, an alkoxycarbonyl group, an alkoxycarbonyloxy group, an acyl group, an acyloxy group, and the like. In light of more improving the LWR performance of the radiation-sensitive resin composition, the condensed polycyclic aromatic hydrocarbon ring is preferably the substituted condensed polycyclic aromatic hydrocarbon ring. The substituent in this case is preferably the halogen atom, more preferably a bromine atom or an iodine atom, and still more preferably an iodine atom. On the other hand, in light of more broadening of the process window of the radiation-sensitive resin composition, the condensed polycyclic aromatic hydrocarbon ring is preferably the unsubstituted condensed polycyclic aromatic hydrocarbon ring.

The lower limit of a proportion of the structural unit (I) included in the polymer (A) is, with respect to total structural units constituting the polymer (A), preferably 5 mol %, more preferably 10 mol %, and still more preferably 20 mol %. The upper limit of the proportion is preferably 70 mol %, more preferably 60 mol %, and still more preferably 50 mol %. When the proportion of the structural unit (I) falls within the above range, the sensitivity, the LWR performance, and the process window of the radiation-sensitive resin composition may be further improved, and/or favorable harmonization can be contemplated. With respect to descriptions of the upper limit and the lower limit of numerical ranges as referred to herein, unless otherwise specified particularly, the upper limit may have the meaning of either “no greater than” or “less than”, and the lower limit may have the meaning of either “no less than” or “greater than”. Further, the upper limit value and the lower limit value may be combined ad libitum.

The polymer (A) having the structural unit (I) can be synthesized in accordance with a well-known procedure, by polymerizing a monomer (hereinafter, may be also referred to as “monomer (X)”) that gives a structural unit (I). The monomer (X) can be obtained in accordance with a well-known procedure by, for example, allowing a compound that gives Ar¹ in the formula (1), such as 9-anthrol, to react with a compound that provides a skeleton structure of the monomer (X), such as methacryloyl chloride.

### Structural Unit (II)

The structural unit (II) is a structural unit that includes an acid-labile group. The “acid-labile group” as referred to herein means a group that substitutes for a hydrogen atom in a carboxy group, a hydroxy group, or the like, and is capable of being dissociated by an action of an acid to give a carboxy group, a hydroxy group, or the like. The acid-labile group is dissociated by an action of the acid generated from the acid generating agent (B), etc. upon exposure, whereby a difference is generated in the solubility of the polymer (A) in the developer solution, between light-exposed regions and light-unexposed regions, and thus forming a resist pattern is enabled. Typically, due to the polymer (A) having the structural unit (II), a property of altering solubility in a developer solution by an action of an acid may be exhibited.

The structural unit (I) is exemplified by a structural unit (hereinafter, may be also referred to as “structural unit (II-1) or (II-2)”) represented by the following formula (II-1) or (II-2), and the like. It is to be noted that, for example, in the following formula (II-1), —C(R^{X})(R^{Y})(R^{Z}), which bonds to an ethereal oxygen atom derived from the carboxy group, corresponds to the acid-labile group.

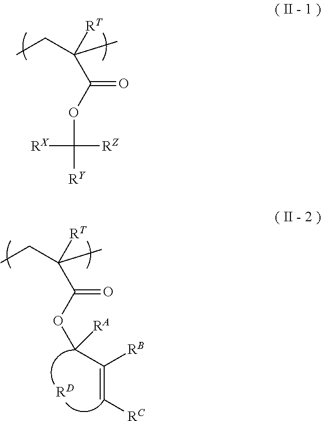

In the above formulae (II-1) and (II-2), R^{T}s each independently represent a hydrogen atom, a fluorine atom, a methyl group, or a trifluoromethyl group.

In the above formula (II-1), R^{X} represents a monovalent hydrocarbon group having 1 to 20 carbon atoms; R^{Y} and R^{Z} each independently represent a monovalent hydrocarbon group having 1 to 20 carbon atoms, or these groups taken together represent a saturated alicyclic ring having 3 to 20 ring atoms, together with the carbon atom to which these bond.

In the above formula (II-2), R^{A} represents a hydrogen atom; R^{B} and R^{C} each independently represent a hydrogen atom or a monovalent hydrocarbon group having 1 to 20 carbon atoms; and R^{D} represents a divalent hydrocarbon group having 1 to 20 carbon atoms constituting an unsaturated alicyclic ring having 4 to 20 ring atoms, together with the carbon atoms to which R^{A}, R^{B}, and R^{C} bond, respectively.

The number of “carbon atoms” means the number of carbon atoms constituting a group. The “hydrocarbon group” encompasses a chain hydrocarbon group, an alicyclic hydrocarbon group, and an aromatic hydrocarbon group. The “hydrocarbon group” may be either a saturated hydrocarbon group or an unsaturated hydrocarbon group. The “chain hydrocarbon group” as referred to herein means a hydrocarbon group not having a ring structure but being constituted with only a chain structure, and may be exemplified by both a linear hydrocarbon group and a branched hydrocarbon group. The “alicyclic hydrocarbon group” as referred to herein means a hydrocarbon group having, as a ring structure, not an aromatic ring but an aliphatic ring alone, and may be exemplified by both a monocyclic alicyclic hydrocarbon group and a polycyclic alicyclic hydrocarbon group. With regard to this, it is not necessary for the alicyclic hydrocarbon group to be constituted with only an aliphatic ring; it may have a chain structure in a part thereof. The “aromatic hydrocarbon group” as referred to herein means a hydrocarbon group that includes an aromatic ring as a ring structure. With regard to this, it is not necessary for the aromatic hydrocarbon group to be constituted with only an aromatic ring, and it may have a chain structure or an aliphatic ring in a part thereof.

The monovalent hydrocarbon group having 1 to 20 carbon atoms which may be represented by R^{X}, R^{Y}, R^{Z}, R^{B}, or R^{C} is exemplified by a monovalent chain hydrocarbon group having 1 to 20 carbon atoms, a monovalent alicyclic hydrocarbon group having 3 to 20 carbon atoms, a monovalent aromatic hydrocarbon group having 6 to 20 carbon atoms, and the like.

Examples of the monovalent chain hydrocarbon group having 1 to 20 carbon atoms include: alkyl groups such as a methyl group, an ethyl group, an n-propyl group, an i-propyl group, an n-butyl group, a sec-butyl group, an isobutyl group, and a tert-butyl group; alkenyl groups such as an ethenyl group, a propenyl group, a butenyl group and a 2-methylprop-1-en-1-yl group; alkynyl groups such as an ethynyl group, a propynyl group, and a butynyl group; and the like

Examples of the monovalent alicyclic hydrocarbon group having 3 to 20 carbon atoms include: monocyclic alicyclic saturated hydrocarbon groups such as a cyclopentyl group and a cyclohexyl group; polycyclic alicyclic saturated hydrocarbon groups such as a norbornyl group, an adamantyl group, a tricyclodecyl group, and a tetracyclododecyl group; monocyclic alicyclic unsaturated hydrocarbon groups such as a cyclopentenyl group and a cyclohexenyl group; polycyclic alicyclic unsaturated hydrocarbon groups such as a norbornenyl group, a tricyclodecenyl group, and a tetracyclododecenyl group; and the like.

Examples of the monovalent aromatic hydrocarbon group having 6 to 20 carbon atoms include: aryl groups such as a phenyl group, a tolyl group, a xylyl group, a naphthyl group, and an anthryl group; aralkyl groups such as a benzyl group, a phenethyl group, a naphthylmethyl group, and an anthrylmethyl group; and the like.

Examples of the saturated aliphatic ring having 3 to 20 ring atoms which may be represented by R^{Y} and R^{Z}, taken together, together with the carbon atom to which R^{Y} and R^{Z} bond include: monocyclic saturated aliphatic rings such as a cyclopropane ring, a cyclobutane ring, a cyclopentane ring, and a cyclohexane ring; polycyclic saturated aliphatic rings such as a norbornane ring, an adamantane ring, a tricyclodecane ring, and a tetracyclododecane ring; and the like.

Examples of the divalent hydrocarbon group having 1 to 20 carbon atoms represented by R^{D} include groups obtained by removing one hydrogen atom from the groups exemplified as the monovalent hydrocarbon group having 1 to 20 carbon atoms which may be represented by the above R^{X}, R^{Y}, R^{Z}, R^{B}, or R^{C}, and the like.

Examples of the unsaturated aliphatic ring having 4 to 20 ring atoms represented by R^{D} together with the carbon atoms to which R^{A}, R^{B}, and R^{C} bond, respectively, include: monocyclic unsaturated aliphatic rings such as a cyclobutene ring, a cyclopentene ring, and a cyclohexene ring; polycyclic unsaturated aliphatic rings such as a norbornene ring; and the like.

R^{T} represents preferably a hydrogen atom or a methyl group, in light of a degree of copolymerization of the monomer that gives a structural unit (II).

R^{X} represents preferably the chain hydrocarbon group or the aromatic hydrocarbon group, more preferably the alkyl group, the alkenyl group, or the aryl group, and still more preferably a methyl group, an ethyl group, an i-propyl group, a tert-butyl group, an ethenyl group, or a phenyl group.

It is preferred that R^{Y} and R^{Z} taken together represent the saturated alicyclic ring having 3 to 20 ring atoms, together with the carbon atom to which R^{Y} and R^{Z} bond. The saturated alicyclic ring is preferably a cyclopentane ring, a cyclohexane ring, an adamantane ring, or a tetracyclododecane ring.

R^{B} represents preferably a hydrogen atom.

R^{C} represents preferably the chain hydrocarbon group, more preferably the alkyl group, and still more preferably a methyl group.

The unsaturated alicyclic ring having 4 to 20 ring atoms constituted from R^{D} together with the carbon atoms to which R^{A}, R^{B}, and R^{C} bond, respectively is preferably a monocyclic unsaturated alicyclic ring, and more preferably a cyclohexene ring.

Examples of the structural unit (II-1) include structural units (hereinafter, may be also referred to as “structural units (II-1-1) to (II-1-9)”) represented by the following formulae (II-1-1) to (II-1-9), and the like. Examples of the structural unit (II-2) include structural units (hereinafter, may be also referred to as “structural units (II-2-1) to (II-2-2)”) represented by the following formulae (II-2-1) to (II-2-2), and the like.

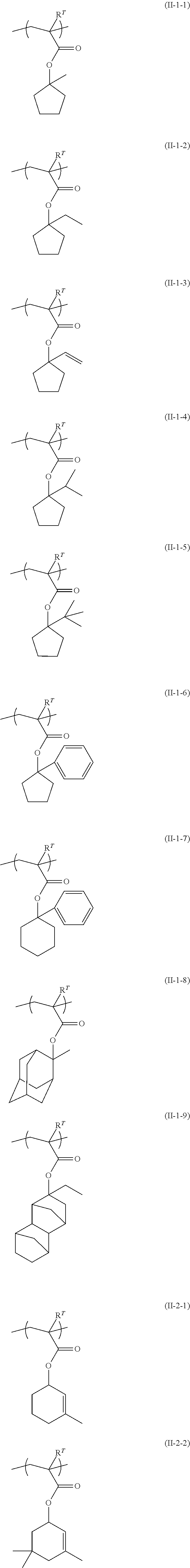

In the above formulae (II-1-1) to (II-9) and (II-2-1) to (II-2-2), R^{T} is as defined in the above formulae (II-2) and (II-2).

The lower limit of a proportion of the structural unit (II) in the polymer (A) with respect to total structural units constituting the polymer (A) is preferably 30 mol %, and more preferably 40 mol %. The upper limit of the proportion is preferably 70 mol %, and more preferably 60 mol %.

### Structural Unit (III)

The structural unit (III) is a structural unit that includes a phenolic hydroxyl group. The “phenolic hydroxyl group” as referred to herein is not limited to a hydroxy group directly bonding to a benzene ring, and means any hydroxy group directly bonding to an aromatic ring in general.

In the case in which the polymer (A) has the structural unit (III), the hydrophilicity of the resist film can be increased, whereby the solubility in the developer solution can be appropriately adjusted, and additionally, adhesiveness of the resist pattern to a substrate can be improved. Furthermore, in a case in which an extreme ultraviolet ray (EUV) or an electron beam is used as a radioactive ray employed for irradiation in an exposure step of the method of forming a resist pattern described later, the sensitivity to exposure light can be further improved. Therefore, in the case in which the polymer (A) has the structural unit (III), the radiation-sensitive resin composition can be particularly suitably used as a radiation-sensitive resin composition for exposure to an extreme ultraviolet ray or for exposure to an electron beam.

Examples of the structural unit (III) include a structural unit (hereinafter, may be also referred to as “structural unit (III-1)”) represented by the following formula (III-1), and the like.

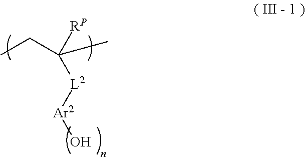

In the above formula (III-1), R^{P} represents a hydrogen atom, a fluorine atom, a methyl group, or a trifluoromethyl group; L² represents a single bond, —COO—, —O—, or —CONH—; Ar² represents a group obtained by removing (n+1) hydrogen atom from a substituted or unsubstituted aromatic hydrocarbon ring having 6 to 30 ring atoms; and n is an integer of 1 to 3.

R^{P} represents preferably a hydrogen atom or a methyl group, in light of a degree of copolymerization of the monomer that gives the structural unit (III-1).

L² represents preferably a single bond or —COO—.

Examples of the aromatic hydrocarbon ring having 6 to 30 ring atoms that gives Ar² include: a benzene ring; condensed polycyclic aromatic hydrocarbon rings such as a naphthalene ring, an anthracene ring, a fluorene ring, a biphenylene ring, a phenanthrene ring, and a pyrene ring; ring-assembled aromatic hydrocarbon rings such as a biphenyl ring, a terphenyl ring, a binaphthalene ring, and a phenylnaphthalene ring; and the like. Of these, a benzene ring or a naphthalene ring is preferred.

The substituent in the case of including the aromatic hydrocarbon ring is exemplified by a halogen atom such as a fluorine atom, and a hydroxy group, a carboxy group, a cyano group, a nitro group, an alkyl group, an alkoxy group, an alkoxycarbonyl group, an alkoxycarbonyloxy group, an acyl group, an acyloxy group, and the like.

It is preferred that n is 1 or 2.

Examples of the structural unit (III-1) include structural unit (hereinafter, may be also referred to as “structural units (III-1-1) to (III-1-12)”) represented by the following formulae (III-1-1) to (III-1-12), and the like.

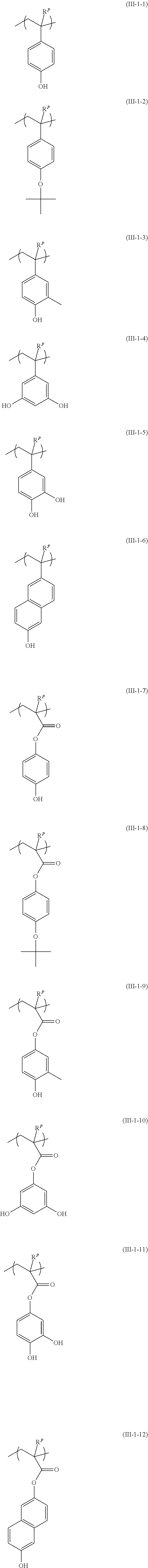

In the above formulae (III-1-1) to (III-1-12), R^{P} is as defined in the above formula (III-1).

In the case in which the polymer (A) has the structural unit (III), the lower limit of a proportion of the structural unit (III) with respect to the total structural units in the polymer (A) is preferably 5 mol %, and more preferably 10 mol %. The upper limit of the proportion is preferably 70 mol %, and more preferably 60 mol %.

### Other Structural Unit(s)

The other structural unit(s) is/are structural unit(s) other than the structural units (I) to (III). The other structural unit(s) may be selected from among structural units derived from well-known monomers used for polymers of radiation-sensitive resin compositions, within a range not leading to impairment of the effects of the present invention. The other structural unit(s) is/are exemplified by: a structural unit (hereinafter, may be also referred to as “structural unit (IV)”) that includes a lactone structure, a cyclic carbonate structure, sultone structure, or a combination of the same; a structural unit (hereinafter, may be also referred to as “structural unit (V)”) that includes an alcoholic hydroxyl group; a structural unit (hereinafter, may be also referred to as “structural unit (VI)”) that generates an acid upon exposure; and the like.

In the case in which the polymer (A) has the other structural unit(s), a proportion of the other structural unit(s) may be determined ad libitum, in accordance with the type, purpose, and/or the like of the other structural unit(s). For example, with respect to the total structural units in the polymer (A), the proportion of the other structural unit(s) may be no less than 1 mol % and no greater than 20 mol %.

### Structural Unit (IV)

The structural unit (IV) is a structural unit that includes a lactone structure, a cyclic carbonate structure, a sultone structure, or a combination of the same. In the case in which the polymer (A) has the structural unit (IV), the hydrophilicity of the resist film can be enhanced and the solubility in a developer solution can be appropriately adjusted.

Examples of the structural unit (IV) include structural units represented by the following formulae, and the like.

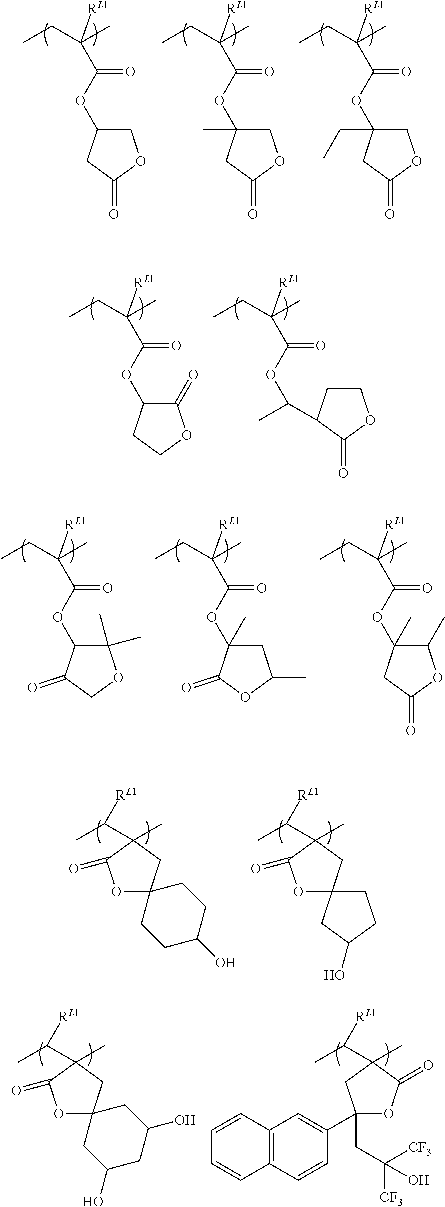

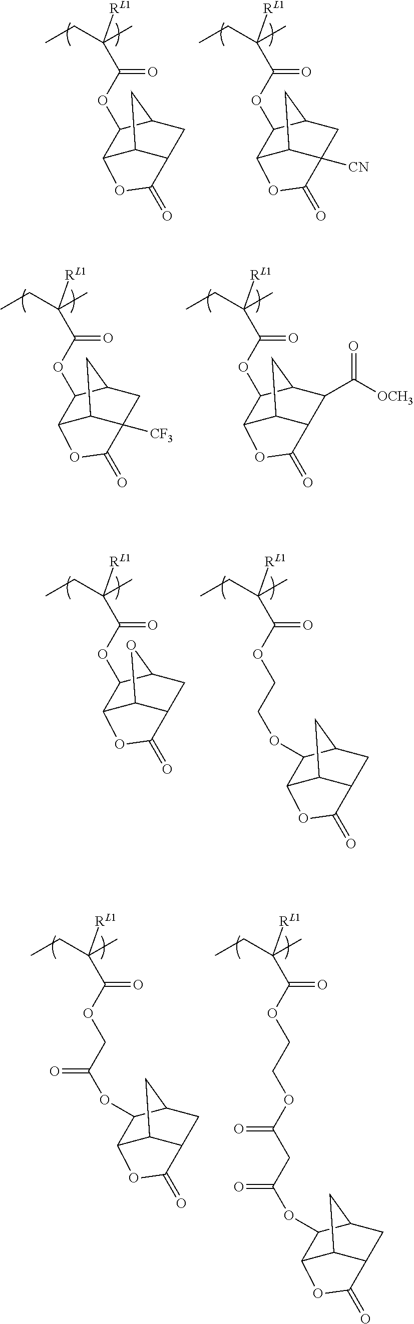

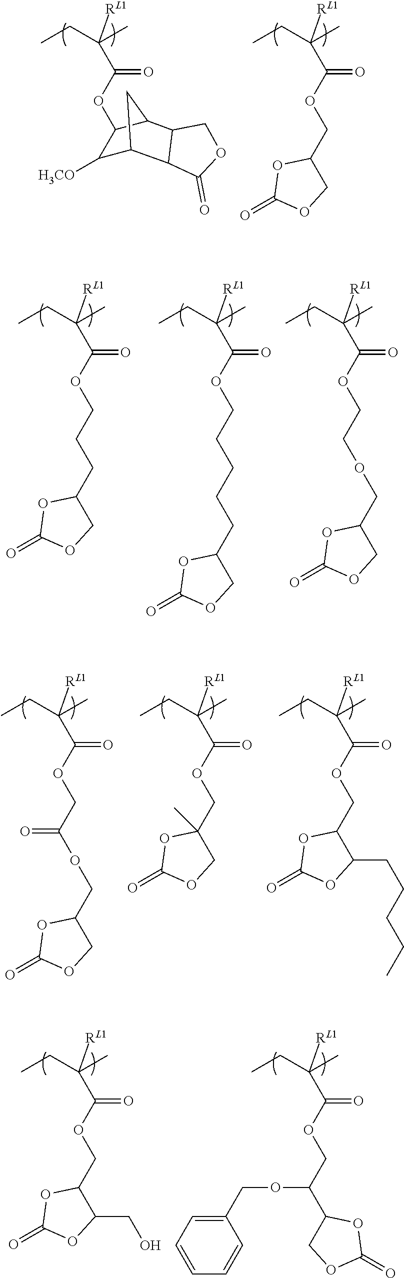

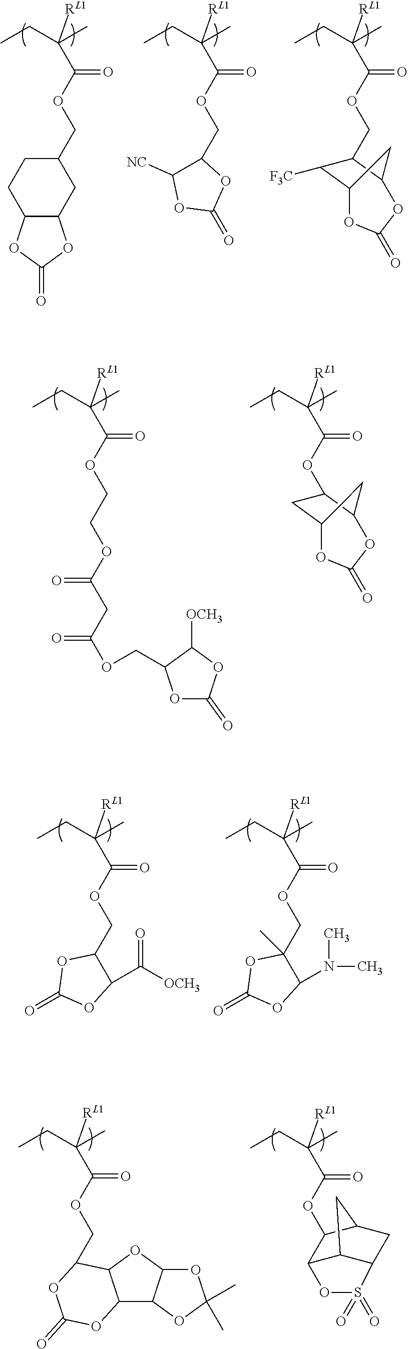

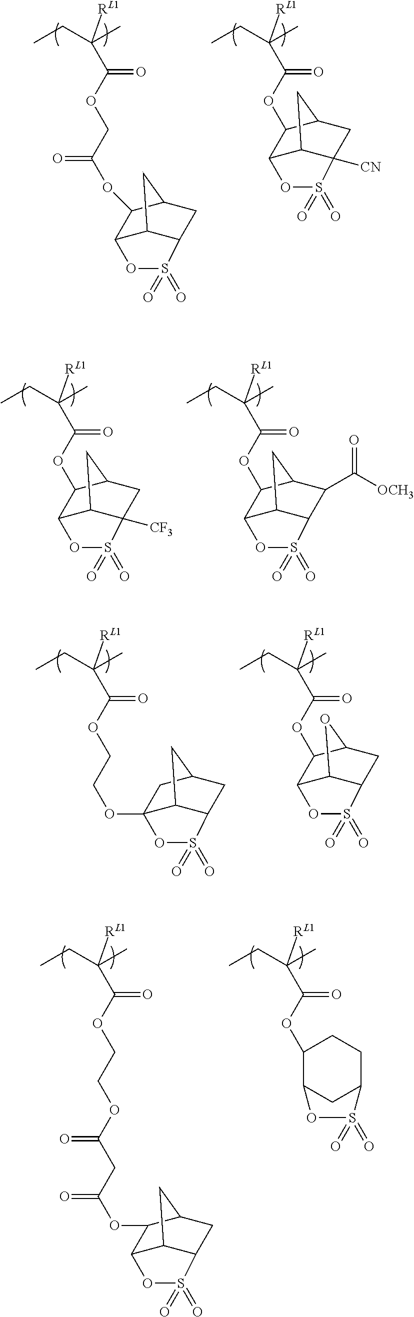

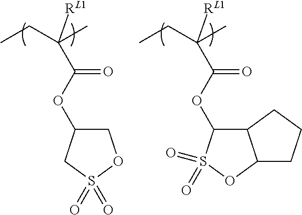

In the above formulae, R^{L1} represents a hydrogen atom, a fluorine atom, a methyl group, or a trifluoromethyl group.

The structural unit (IV) is preferably a structural unit that includes a lactone structure, a cyclic carbonate structure, or a combination of the same.

### Structural Unit (V)

The structural unit (V) is as structural unit that includes an alcoholic hydroxyl group. In the case in which the polymer (A) has the structural unit (V), the hydrophilicity of the resist film can be enhanced, the solubility in a developer solution can be appropriately adjusted, and in addition, adhesiveness of the resist pattern to the substrate can be improved.

Examples of the structural unit (V) include structural units represented by the following formulae, and the like.

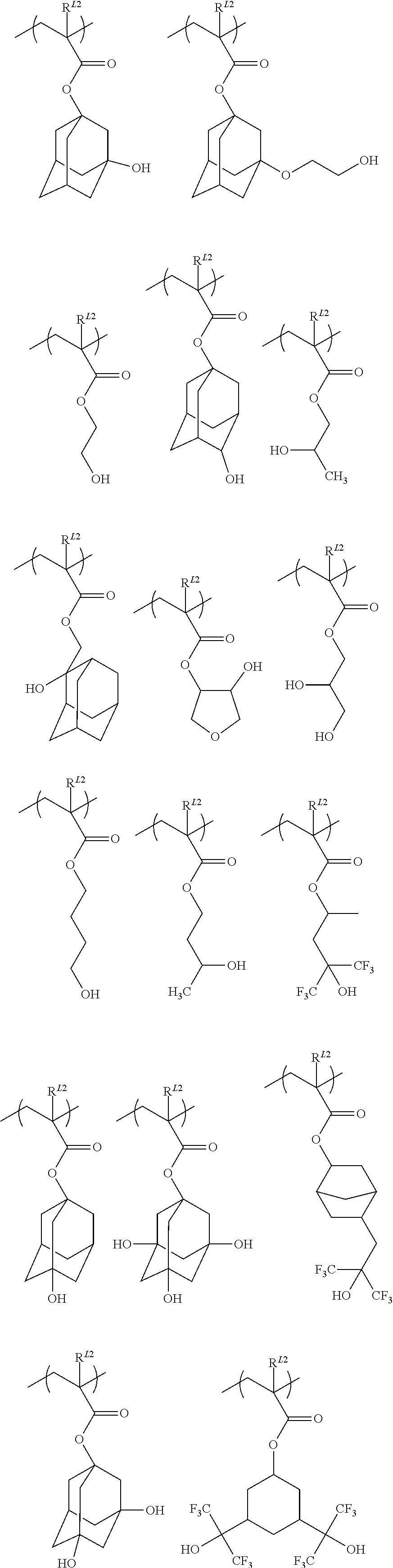

In the above formulae, R^{L2} represents a hydrogen atom, a fluorine atom, a methyl group, or a trifluoromethyl group.

### Structural Unit (VI)

The structural unit (VI) is a structural unit that generates an acid upon exposure. In the case in which the polymer (A) has the structural unit (VI), the polymer (A) may also serve as a radiation-sensitive acid generator.

Examples of the structural unit (VI) include a structural unit represented by the following formula, and the like.

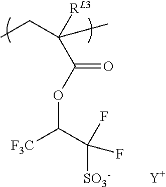

In the above formula, R^{L3} represents a hydrogen atom, a fluorine atom, a methyl group, or a trifluoromethyl group; and Y⁺ represents a monovalent radiation-sensitive onium cation.

The monovalent radiation-sensitive onium cation represented by Y⁺ may be exemplified by monovalent radiation-sensitive onium cations similar to those exemplified as the monovalent radiation-sensitive onium cation in the acid diffusion control agent (C) described below, and the like.

### (B) Acid Generating Agent

The acid generating agent (B) is a substance that generates an acid upon exposure. The exposure light may be exemplified by exposure light similar to those exemplified as the exposure light in the exposing step of the method of forming a resist pattern of the other embodiment of the present disclosure, described later, and the like. The acid thus generated upon exposure allows the acid-labile group included in the polymer (A) or the like to be dissociated, thereby generating a carboxy group, a hydroxy group, etc., whereby a difference in solubility of the resist film in the developer solution is generated between the light-exposed regions and the light-unexposed regions, and thus formation of the resist pattern is enabled.

Examples of the acid generated from the acid generating agent (B) include sulfonic acid, imidic acid, and the like.

The acid generating agent (B) is exemplified by an onium salt compound, an N-sulfonyloxyimide compound, a sulfonimide compound, a halogen-containing compound, a diazoketone compound, and the like.

Examples of the onium salt compound include sulfonium salts, tetrahydrothiophenium salts, iodonium salts, phosphonium salts, diazonium salts, pyridinium salts, and the like.

Specific examples of the acid generating agent (B) include compounds disclosed in paragraphs [0080] to [0113] of Japanese Unexamined Patent Application, Publication No. 2009-134088, and the like.

Examples of the acid generating agent (B) which generates sulfonic acid upon exposure include a compound (hereinafter, may be also referred to as “(B) compound” or “compound (B)”) represented by the following formula (4), and the like.

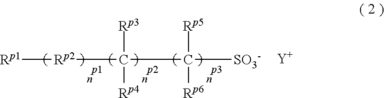

In the above formula (2), R^{p1} represents a monovalent group that includes a ring structure having 5 or more ring atoms; R^{p2} represents a divalent linking group; R^{p3} and R^{p4} each independently represent a hydrogen atom, a fluorine atom, a monovalent hydrocarbon group having 1 to 20 carbon atoms, or a monovalent fluorinated hydrocarbon group having 1 to 20 carbon atoms; R^{p5} and R^{p6} each independently represent a fluorine atom or a monovalent fluorinated hydrocarbon group having 1 to 20 carbon atoms; n^{p1} is an integer of 0 to 10, n^{p2} is an integer of 0 to 10, and n^{p3} is an integer of 0 to 10, wherein in a case in which n^{p1} is no less than 2, a plurality of R^{p2}s are identical or different from each other, in a case in which n^{p2} is no less than 2, a plurality of R^{p3}s are identical or different from each other and a plurality of R^{p4}s are identical or different from each other, and in a case in which n^{p3} is no less than 2, a plurality of R^{p5}s are identical or different from each other and a plurality of R^{p6}s are identical or different from each other; and Y⁺ represents a monovalent radiation-sensitive onium cation.

The ring structure having 5 or more ring atoms in R^{p1} is exemplified by an aliphatic ring having 5 or more ring atoms, an aliphatic heteroring having 5 or more ring atoms, an aromatic hydrocarbon ring having 6 or more ring atoms, and an aromatic heteroring having 5 or more ring atoms.

Examples of the aliphatic ring having 5 or more ring atoms include: monocyclic saturated aliphatic rings such as a cyclopentane ring, a cyclohexane ring, a cycloheptane ring, a cyclooctane ring, a cyclononane ring, a cyclodecane ring, and a cyclododecane ring; monocyclic unsaturated aliphatic rings such as a cyclopentene ring, a cyclohexene ring, a cycloheptene ring, a cyclooctene ring, and a cyclodecene ring; polycyclic saturated aliphatic rings such as a norbornane ring, an adamantane ring, a tricyclodecane ring, and a tetracyclododecane ring; and polycyclic unsaturated aliphatic rings such as a norbornene ring and a tricyclodecene ring.

Examples of the aliphatic heteroring having 5 or more ring atoms include: lactone rings such as a hexanolactone ring and a norbornanelactone ring; sultone rings such as a hexanosultone ring and a norbornanesultone ring; oxygen atom-containing heterorings such as an oxacycloheptane ring, an oxanorbornane ring, and an acetal ring; nitrogen atom-containing heterorings such as an azacyclohexane ring and a diazabicyclooctane ring; and sulfur atom-containing heterorings such as a thiacyclohexane ring and a thianorbornane ring.

Examples of the aromatic hydrocarbon ring having 6 or more ring atoms include a benzene ring, a naphthalene ring, a phenanthrene ring, an anthracene ring, and a 9,10-ethanoanthracene ring.

Examples of the aromatic heteroring having 5 or more ring atoms include: oxygen atom-containing heterorings such as a furan ring, a pyran ring, a benzofuran ring, and a benzopyran ring; and nitrogen atom-containing heterorings such as a pyridine ring, a pyrimidine ring, and an indole ring.

The lower limit of the number of ring atoms of the ring structure in R^{p1} is preferably 6, more preferably 8, still more preferably 9, and particularly preferably 10. The upper limit of the number of ring atoms is preferably 15, more preferably 14, still more preferably 13, and particularly preferably 12. When the number of ring atoms falls within the above range, the diffusion length of the acid can be further properly decreased, and as a result, the sensitivity and the LWR performance of the radiation-sensitive resin composition can be further improved, and a process window can be further expanded.

A part or all of hydrogen atoms included in the ring structure of R^{p1} may be substituted with a substituent. Examples of the substituent include halogen atoms such as a fluorine atom, a chlorine atom, a bromine atom and an iodine atom, a hydroxy group, a carboxy group, a cyano group, a nitro group, an alkoxy group, an alkoxycarbonyl group, an alkoxycarbonyloxy group, an acyl group, an acyloxy group, and the like. Of these, a hydroxy group, a fluorine atom, or an iodine atom is preferred.

R^{p1} represents preferably a monovalent group that includes an alicyclic ring having 5 or more ring atoms, a monovalent group that includes an aromatic hydrocarbon ring having 6 or more ring atoms, or a monovalent group that includes an aliphatic heterocyclic ring having 5 or more ring atoms, and more preferably a monovalent group that includes a polycyclic saturated alicyclic ring, a monovalent group that includes an iodine atom-containing aromatic hydrocarbon ring having 6 or more ring atoms, a monovalent group that includes an oxygen atom-containing heterocyclic ring, or a monovalent group that includes a sulfur atom-containing heterocyclic ring.

Examples of the divalent linking group represented by R^{p2} include a carbonyl group, an ether group, a carbonyloxy group, a sulfide group, a thiocarbonyl group, a sulfonyl group, a divalent hydrocarbon group, and the like.

The monovalent hydrocarbon group having 1 to 20 carbon atoms which may be represented by each of R^{p1} and R^{p4} is exemplified by an alkyl group having 1 to 20 carbon atoms, and the like. The monovalent fluorinated hydrocarbon group having 1 to 20 carbon atoms which may be represented by each of R^{p1} and R^{p4} is exemplified by a fluorinated alkyl group having 1 to 20 carbon atoms, and the like. R^{p3} and R^{p4} each independently represent preferably a hydrogen atom, a fluorine atom, or a fluorinated alkyl group, more preferably a hydrogen atom, a fluorine atom, or a perfluoroalkyl group, and still more preferably a hydrogen atom, a fluorine atom, or a trifluoromethyl group.

The monovalent fluorinated hydrocarbon group having 1 to 20 carbon atoms which may be represented by each of R^{p1} and R^{p6} is exemplified by a fluorinated alkyl group having 1 to 20 carbon atoms, and the like. R^{p5} and R^{p6} each independently represent preferably a fluorine atom or a fluorinated alkyl group, more preferably a fluorine atom or a perfluoroalkyl group, still more preferably a fluorine atom or a trifluoromethyl group, and particularly preferably a fluorine atom.

n^{p1} is preferably 0 to 5, more preferably 0 to 2, and still more preferably 0 or 1.

n^{p2} is preferably 0 to 5, more preferably 0 to 2, and still more preferably 0 or 1.

The lower limit of n^{p3} is preferably 1, and more preferably 2. When n^{p3} is no less than 1, strength of the acid can be enhanced. The upper limit of n^{p3} is preferably 4, more preferably 3, and still more preferably 2.

The monovalent radiation-sensitive onium cation represented by Y⁺ may be exemplified by monovalent radiation-sensitive onium cations similar to those exemplified as the monovalent radiation-sensitive onium cation in the acid diffusion control agent (C) described below, and the like.

Examples of the compound (B) include compounds represented by the following formulae (2-1) to (2-11), and the like.

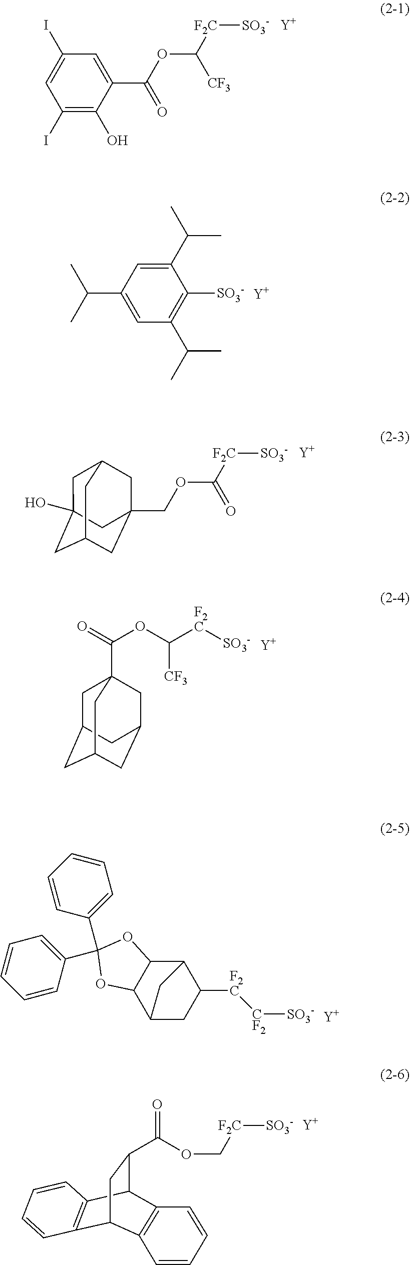

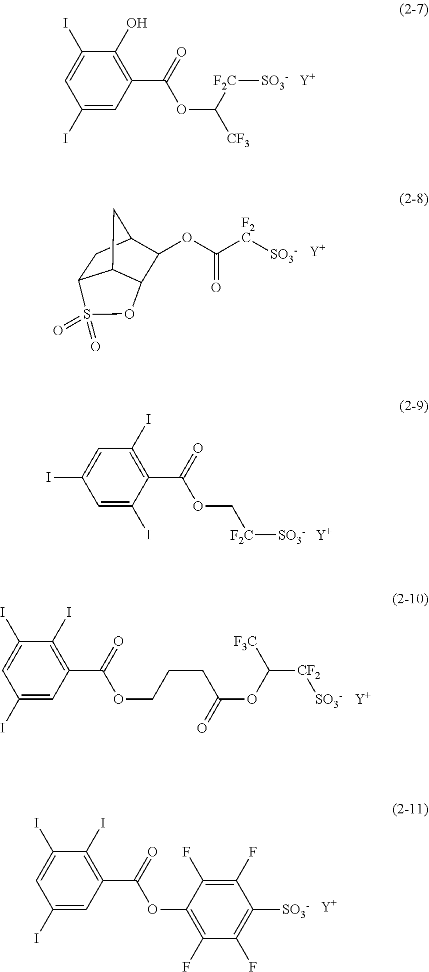

In the above formulae (2-1) to (2-11), Y⁺ is as defined in the above formula (2).

The lower limit of a content of the acid generating agent (B) in the radiation-sensitive resin composition, with respect to 100 parts by mass of the polymer (A), is preferably 1 part by mass, more preferably 5 parts by mass, and still more preferably 10 parts by mass. The upper limit of the content is preferably 50 parts by mass, more preferably 40 parts by mass, and still more preferably 30 parts by mass.

### (C) Acid Diffusion Control Agent

The acid diffusion control agent (C) is a compound having a monovalent radiation-sensitive onium cation and a monovalent organic acid anion. The acid diffusion control agent (C) is able to control a diffusion phenomenon, in the resist film, of the acid generated from the acid generating agent (B), etc. upon exposure, thereby serving to inhibit unwanted chemical reactions in light-unexposed regions. Due to being a compound that generates an acid upon exposure, the acid diffusion control agent can be referred to as an acid generating agent in a broad sense; however, under conditions in which the acid generated from the acid generating agent (B) upon exposure allows for dissociation of an acid-labile group, the acid diffusion control agent (C) generates an acid not causing dissociation of the acid-labile group upon the exposure.

Examples of the monovalent radiation-sensitive onium cation include monovalent cations (hereinafter, may be also referred to as “cations (r-a) to (r-b)”) represented by the following formulae (r-a) to (r-b), and the like.

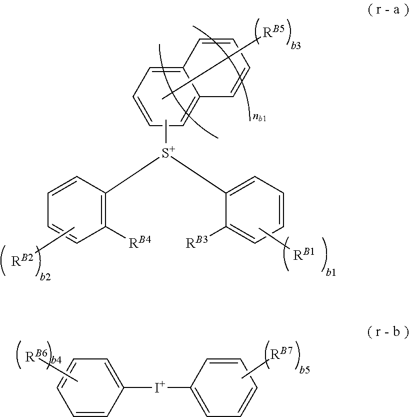

In the above formula (r-a), b1 is an integer of 0 to 4, wherein in a case in which b1 is 1, R^{B1} represents a halogen atom, a hydroxy group, a nitro group, or a monovalent organic group having 1 to 20 carbon atoms, and in a case in which b1 is no less than 2, a plurality of R^{B1}s are identical or different from each other, and each R^{B1} represents a halogen atom, a hydroxy group, a nitro group, or a monovalent organic group having 1 to 20 carbon atoms, or the plurality of R^{B1}s taken together represent a ring structure having 4 to 20 ring atoms together with the carbon chain to which the plurality of R^{B1}s bond; b2 is an integer of 0 to 4, wherein in a case in which b2 is 1, R^{B2} represents a halogen atom, a hydroxy group, a nitro group, or a monovalent organic group having 1 to 20 carbon atoms, and in a case in which b2 is no less than 2, a plurality of R^{B2}s are identical or different from each other, and each R^{B2} represents a halogen atom, a hydroxy group, a nitro group, or a monovalent organic group having 1 to 20 carbon atoms, or the plurality of R^{B2}s taken together represent a ring structure having 4 to 20 ring atoms together with the carbon chain to which the plurality of R^{B2}s bond; R^{B3} and R^{B4} each independently represent a hydrogen atom, a halogen atom, a hydroxy group, a nitro group, or a monovalent organic group having 1 to 20 carbon atoms, or R^{B3} and R^{B4} taken together represent a single bond; b3 is an integer of 0 to 11, wherein in a case in which b3 is 1, R^{B5} represents a halogen atom, a hydroxy group, a nitro group, or a monovalent organic group having 1 to 20 carbon atoms, and in a case in which b3 is no less than 2, a plurality of R^{B5}s are identical or different from each other, and each R^{B5} represents a halogen atom, a hydroxy group, a nitro group, or a monovalent organic group having 1 to 20 carbon atoms, or the plurality of R^{B5s} taken together represent a ring structure having 4 to 20 ring atoms together with the carbon chain to which the plurality of R^{B5}s bond; and n_{b1} is an integer of 0 to 3.

In the above formula (r-b), b4 is an integer of 0 to 5, wherein in a case in which b4 is 1, R^{B6} represents a halogen atom, a hydroxy group, a nitro group, or a monovalent organic group having 1 to 20 carbon atoms, and in a case in which b4 is no less than 2, a plurality of R^{B6}s are identical or different from each other, and each R^{B6} represents a halogen atom, a hydroxy group, a nitro group, or a monovalent organic group having 1 to 20 carbon atoms, or the plurality of R^{B6}s taken together represent a ring structure having 4 to 20 ring atoms together with the carbon chain to which the plurality of R^{B6}s groups bond; b5 is an integer of 0 to 5, wherein in a case in which b5 is 1, R^{B7} represents a halogen atom, a hydroxy group, a nitro group, or a monovalent organic group having 1 to 20 carbon atoms, and in a case in which b5 is no less than 2, a plurality of R^{B7}s are identical or different from each other, and each R^{B7} represents a halogen atom, a hydroxy group, a nitro group, or a monovalent organic group having 1 to 20 carbon atoms, or the plurality of R^{B7}s taken together represent a ring structure having 4 to 20 ring atoms together with the carbon chain to which the plurality of R^{B7}s bond.

The “organic group” as referred to means a group having at least one carbon atom.

The monovalent organic group having 1 to 20 carbon atoms which may be represented by each of R^{B1}, R^{B2}, R^{B3}, R^{B4}, R^{B5}, and R^{B6} is exemplified by: a monovalent hydrocarbon group having 1 to 20 carbon atoms; a group (a) that includes a divalent heteroatom-containing group between two adjacent carbon atoms of the monovalent hydrocarbon group; a group (β) obtained by substituting, with a monovalent heteroatom-containing group, a part or all of hydrogen atoms included in the monovalent hydrocarbon group or the group (α); a group (γ) in which the monovalent hydrocarbon group, the group (α), or the group (β) is combined with a divalent heteroatom-containing group; and the like.

Examples of the monovalent hydrocarbon group having 1 to 20 carbon atoms include groups similar to the groups exemplified as the monovalent hydrocarbon group having 1 to 20 carbon atoms which may be represented by R^{X}, R^{Y} or R^{Z} in the above formula (11-1), and the like.

The heteroatom which may constitute the monovalent or divalent heteroatom-containing group is exemplified by an oxygen atom, a nitrogen atom, a sulfur atom, a phosphorus atom, a silicon atom, a halogen atom, and the like. Examples of the halogen atom include a fluorine atom, a chlorine atom, a bromine atom, and an iodine atom.

Examples of the divalent heteroatom-containing group include —O—, —CO—, —S—, —CS—, —NR′—, groups in which at least two of the aforementioned groups are combined (for example, —COO—, —CONR′—, etc.), and the like, wherein R′ represents a hydrogen atom or a monovalent hydrocarbon group having 1 to 10 carbon atoms.

Each of R^{B1}, R^{B2}, R^{B3}, R^{B4}, R^{B5} and R^{B6} preferably represents a halogen atom or a group obtained by substituting, with a monovalent halogen atom, a part or all of hydrogen atoms included in the monovalent hydrocarbon group having 1 to 20 carbon atoms. The halogen atom in this case is preferably a fluorine atom. In this case, favorable harmonization of the sensitivity, the LWR performance, and the process window of the radiation-sensitive resin composition can be attempted.

R^{B3} and R^{B4} preferably each represent a hydrogen atom, or taken together represent a single bond.

b1, b2 and b3 are preferably 0 to 3. n_{b1} is preferably 0 or 1.

b4 and b5 are preferably 0 or 1.

Examples of the cation (r-a) include cations (hereinafter, may be also referred to as “cations (r-a-1) to (r-a-12)”) represented by the following formulae (r-a-1) to (r-a-12), and the like. Examples of the cation (r-b) include a cation (hereinafter, may be also referred to as “cation (r-b-1)”) represented by the following formula (r-b-1), and the like.

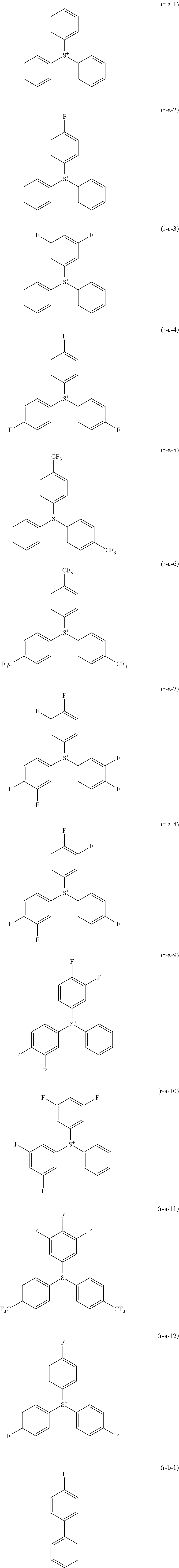

The monovalent organic acid anion is exemplified by a carboxylate anion and the like. Examples of the carboxylate anion include anions (hereinafter, may be also referred to as “anions (3-1) to (3-9)”) represented by the following formulae (3-1) to (3-9).

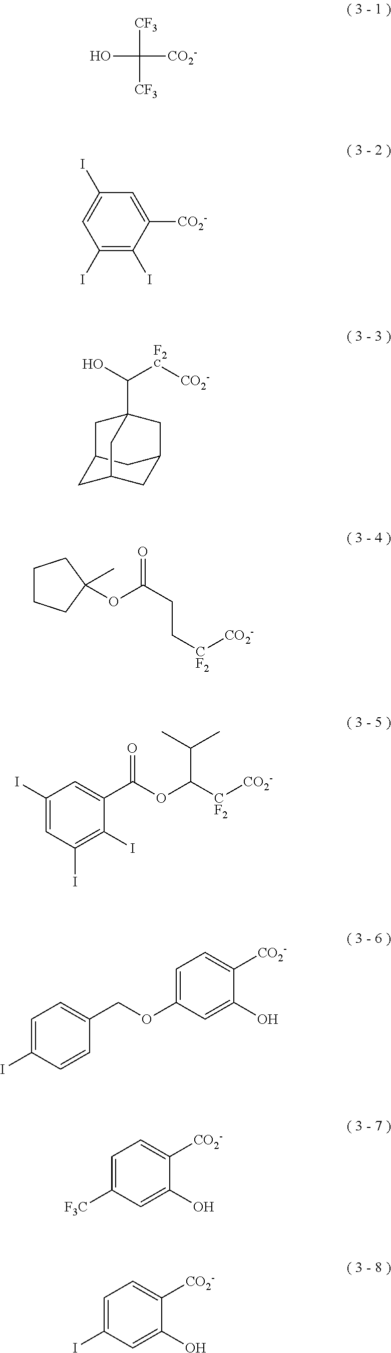

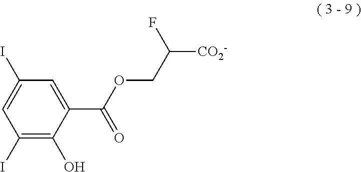

As the acid diffusion control agent (C), a compound in which the cation is combined with the anion can be used.

The lower limit of a content of the acid diffusion control agent (C) in the radiation-sensitive resin composition with respect to 100 mol % of the acid generating agent (B) is preferably 1 mol %, more preferably 5 mol %, and still more preferably 10 mol %. The upper limit of the content is preferably 100 mol %, more preferably 50 mol %, and still more preferably 30 mol %.

### (D) Organic Solvent

The radiation-sensitive resin composition typically contains the organic solvent (D). The organic solvent (D) is not particularly limited as long as it is a solvent capable of dissolving or dispersing at least the polymer (A), the acid generating agent (B), and the acid diffusion control agent (C), as well as the other optional component(s), and the like, which is/are contained as needed.

The organic solvent (D) is exemplified by an alcohol solvent, an ether solvent, a ketone solvent, an amide solvent, an ester solvent, a hydrocarbon solvent, and the like. One, or two or more types of the organic solvent (D) may be contained.

Examples of the alcohol solvent include:
aliphatic monohydric alcohol solvents having 1 to 18 carbon atoms such as 4-methyl-2-pentanol and n-hexanol;
alicyclic monohydric alcohol solvents having 3 to 18 carbon atoms such as cyclohexanol;
polyhydric alcohol solvents having 2 to 18 carbon atoms such as 1,2-propylene glycol;
polyhydric alcohol partial ether solvents having 3 to 19 carbon atoms such as propylene glycol monomethyl ether; and the like.

Examples of the ether solvent include:
dialkyl ether solvents such as diethyl ether, dipropyl ether, dibutyl ether, dipentyl ether, diisoamyl ether, dihexyl ether, and diheptyl ether;
cyclic ether solvents such as tetrahydrofuran and tetrahydropyran;
aromatic ring-containing ether solvents such as diphenyl ether and anisole; and the like.

Examples of the ketone solvent include:
chain ketone solvents such as acetone, methyl ethyl ketone, methyl n-propyl ketone, methyl n-butyl ketone, diethyl ketone, methyl iso-butyl ketone, 2-heptanone, ethyl n-butyl ketone, methyl n-hexyl ketone, di-iso-butyl ketone, and trimethyl nonanone;
cyclic ketone solvents such as cyclopentanone, cyclohexanone, cycloheptanone, cyclooctanone, and methylcyclohexanone;
2,4-pentanedione, acetonylacetone, and acetophenone; and the like.

Examples of the amide solvent include:
cyclic amide solvents such as N,N′-dimethylimidazolidinone and N-methylpyrrolidone;
chain amide solvents such as N-methylformamide, N,N-dimethylformamide, N,N-diethylformamide, acetamide, N-methylacetamide, N,N-dimethylacetamide, and N-methylpropionamide; and the like.

Examples of the ester solvent include:
monocarboxylic acid ester solvents such as n-butyl acetate and ethyl lactate;
lactone solvents such as γ-butyrolactone and valerolactone;
polyhydric alcohol carboxylate solvents such as propylene glycol acetate;
polyhydric alcohol partial ether carboxylate solvents such as propylene glycol monomethyl ether acetate;
polyhydric carboxylic acid diester solvents such as diethyl oxalate;
carbonate solvents such as dimethyl carbonate and diethyl carbonate; and the like.

Examples of the hydrocarbon solvent include:
aliphatic hydrocarbon solvents having 5 to 12 carbon atoms such as n-pentane and n-hexane;
aromatic hydrocarbon solvents having 6 to 16 carbon atoms such as toluene and xylene; and the like.

The organic solvent (D) is preferably the alcohol solvent, the ester solvent, or a combination of the same, more preferably the polyhydric alcohol partial ether solvent having 3 to 19 carbon atoms, the polyhydric alcohol partial ether carboxylate solvent, or a combination of the same, and still more preferably propylene glycol monomethyl ether, propylene glycol monomethyl ether acetate, or a combination of the same.

In the case of the radiation-sensitive resin composition containing the organic solvent (D), the lower limit of a proportion of the organic solvent (D) with respect to total components contained in the radiation-sensitive resin composition is preferably 50% by mass, more preferably 60% by mass, still more preferably 70% by mass, and particularly preferably 80% by mass. The upper limit of the proportion is preferably 99.9% by mass, more preferably 99.5% by mass, and still more preferably 99.0% by mass.

### Other Optional Component(s)

The other optional component(s) is/are exemplified by a surfactant and the like. The radiation-sensitive resin composition may contain one, or two or more types each of the other optional component(s).

### Method of Forming Resist Pattern

The method of forming a resist pattern according to the other embodiment of the present disclosure includes: a step (hereinafter, may be also referred to as “applying step”) of applying a radiation-sensitive resin composition directly or indirectly on a substrate; a step (hereinafter, may be also referred to as “exposing step”) of exposing a resist film formed by the applying; and a step (hereinafter, may be also referred to as “developing step”) of developing the resist film exposed.

In the applying step, the radiation-sensitive resin composition of the one embodiment of the present disclosure, described above, is used as the radiation-sensitive resin composition. Therefore, according to the method of forming a resist pattern, forming a resist pattern that is superior in sensitivity and LWR performance, with a broad process window is enabled.

Each step included in the method of forming a resist pattern will be described below.

### Applying Step

In this step, the radiation-sensitive resin composition is applied directly or indirectly on the substrate. By this step, the resist pattern is formed directly or indirectly on the substrate.

In this step, the radiation-sensitive resin composition of the one embodiment of the present disclosure, described above, is used as the radiation-sensitive resin composition.

The substrate is exemplified by a conventionally well-known substrate such as a silicon wafer, a wafer coated with silicon dioxide or aluminum, and the like.

An application procedure is exemplified by spin coating, cast coating, roll coating, and the like. After the application, prebaking (hereinafter, may be also referred to as “PB”) may be carried out as needed for evaporating the solvent remaining in the coating film. The lower limit of a PB temperature is preferably 60° C., and more preferably 80° C. The upper limit of the PB temperature is preferably 150° C., and more preferably 140° C. The lower limit of a PB time period is preferably 5 sec, and more preferably 10 sec. The upper limit of the PB time period is preferably 600 sec, and more preferably 300 sec. The lower limit of an average thickness of the resist film formed is preferably 10 nm, and more preferably 20 nm. The upper limit of the average thickness is preferably 1,000 nm, and more preferably 500 nm.

### Exposing Step

In this step, the resist film formed by the applying step is exposed. This exposure is carried out by irradiation with an exposure light through a photomask (as the case may be, through a liquid immersion medium such as water). As the exposure light, far ultraviolet rays, EUV, or electron beams are preferred; an ArF excimer laser beam (wavelength: 193 nm), a KrF excimer laser beam (wavelength: 248 nm), EUV (wavelength: 13.5 mm), or an electron beam is more preferred; a KrF excimer laser beam, EUV, or an electron beam is still more preferred; and EUV or an electron beam is particularly preferred.

It is preferred that post exposure baking (hereinafter, may be also referred to as “PEB”) is carried out after the exposure. This PEB enables increasing a difference in solubility of the resist film in a developer solution between the light-exposed regions and light-unexposed regions. The lower limit of a PEB temperature is preferably 50° C., and more preferably 80° C. The upper limit of the PEB temperature is preferably 180° C., and more preferably 130° C. The lower limit of a PEB time period is preferably 5 sec, more preferably 10 sec, and still more preferably 30 sec. The upper limit of the PEB time period is preferably 600 sec, more preferably 300 sec, and still more preferably 100 sec.

### Developing Step

In this step, the resist film exposed is developed. Accordingly, formation of a predetermined resist pattern is enabled. The development procedure in the developing step may be carried out by either development with an alkali, or development with an organic solvent.

In the case of the development with an alkali, the developer solution for use in the development is exemplified by: alkaline aqueous solutions prepared by dissolving at least one alkaline compound such as sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethylamine, ethyldimethylamine, triethanolamine, tetramethylammonium hydroxide (hereinafter, may be also referred to as “TMAH”), pyrrole, piperidine, choline, 1,8-diazabicyclo-[5.4.0]-7-undecene, and 1,5-diazabicyclo-[4.3.0]-5-nonene; and the like. Of these, an aqueous TMAH solution is preferred, and a 2.38% by mass aqueous TMAH solution is more preferred.

In the case of the development with an organic solvent, the developer solution is exemplified by: an organic solvent such as a hydrocarbon solvent, an ether solvent, an ester solvent, a ketone solvent, and an alcohol solvent; a solution containing the organic solvent; and the like. An exemplary organic solvent includes the solvents exemplified as the organic solvent (D) in the radiation-sensitive resin composition of the one embodiment of the present disclosure, and the like.

### EXAMPLES

Hereinafter, the present invention is explained in detail by way of Examples, but the present invention is not in any way limited to these Examples. Measuring methods for various types of physical property values are shown below.

### Weight Average Molecular Weight (Mw), Number Average Molecular Weight (Mn), and Polydispersity Index (Mw/Mn)

Measurements of the Mw and the Mn of the polymer were carried out in accordance with the conditions described in the aforementioned paragraph “Method for measuring Mw and Mn”. The polydispersity index (Mw/Mn) of the polymer was calculated from the measurement results of the Mw and the Mn.

### Synthesis of Monomer (X)

According to the following procedure, compounds (hereinafter, may be also referred to as “monomers (X-1) to (X-34)”) represented by the following formulae (X-1) to (X-34) as the monomer (X) were synthesized.

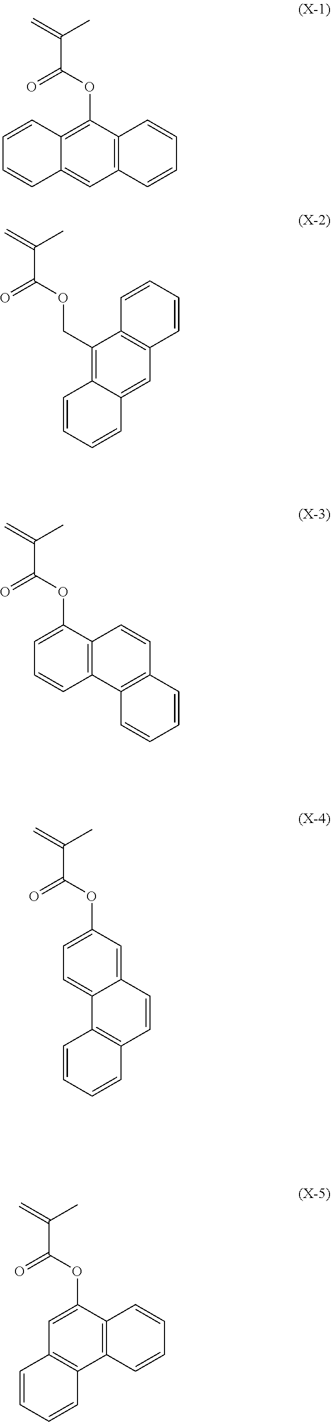 [SMILES: C=C(C)C(=O)Oc1c2ccccc2cc2ccccc12 ; C=C(C)C(=O)OCc1c2ccccc2cc2ccccc12 ; C=C(C)C(=O)Oc1cccc2c1ccc1ccccc12 ; C=C(C)C(=O)Oc1ccc2c(ccc3ccccc32)c1 ; C=C(C)C(=O)Oc1cc2ccccc2c2ccccc12]

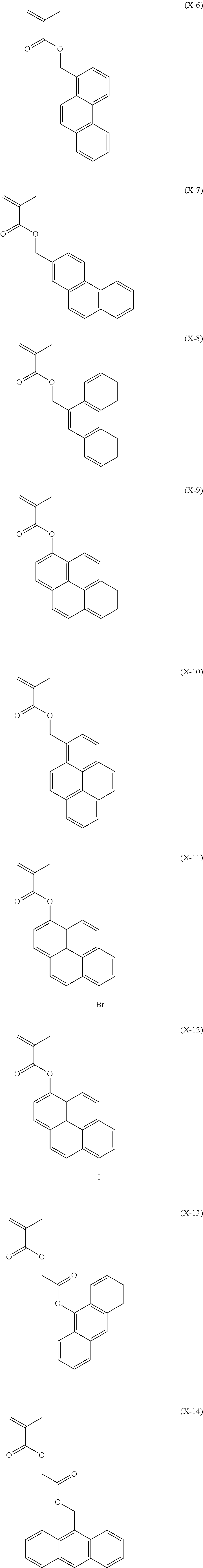

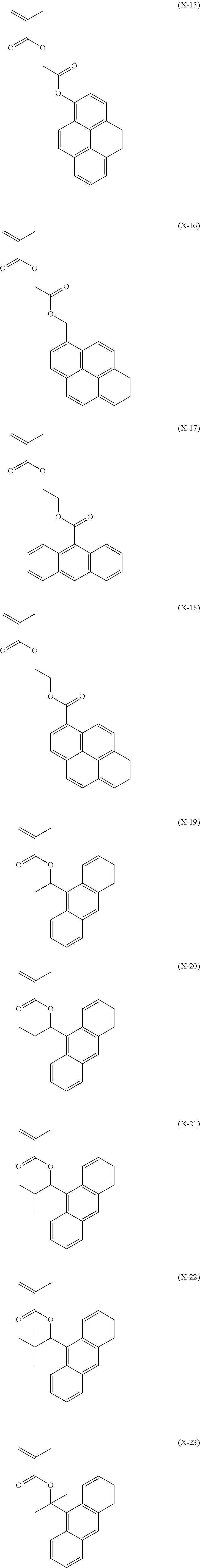

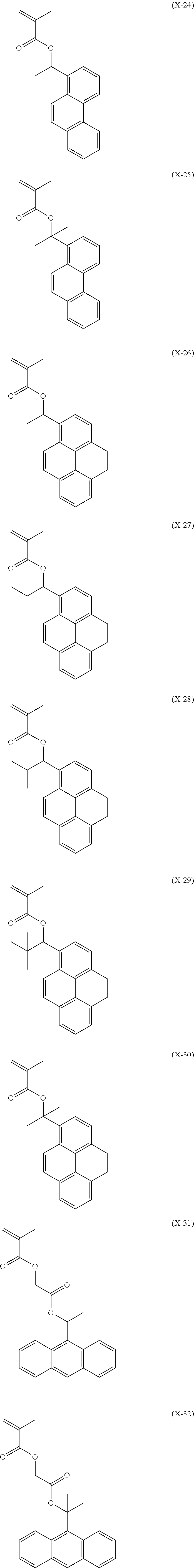

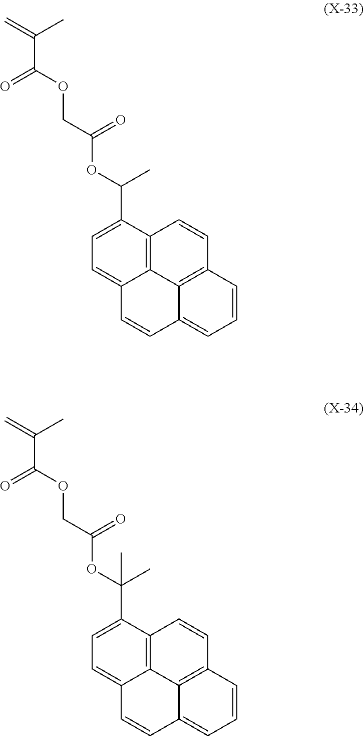 [SMILES: C=C(C)C(=O)OCC(=O)OC(C)c1ccc2ccc3cccc4ccc1c2c34 ; C=C(C)C(=O)OCC(=O)OC(C)(C)c1ccc2ccc3cccc4ccc1c2c34]

### Synthesis Example 1-1: Synthesis of Monomer (X-1)

In 1,500 mL of dichloromethane, 200 g of 9-anthrol and 156 g of triethylamine were dissolved. After a thus resulting solution was cooled to 0° C., 108 g of methacryloyl chloride was added dropwise at a rate not leading to temperature rise exceeding 25° C. After completion of the dropwise addition, the solution was stirred at 25° C. for 1 hour. Completion of the reaction was followed by quenching with a saturated aqueous ammonium chloride solution, and by extraction with methylene chloride. A residue obtained by concentration in vacuo was subjected to purification by column chromatography, whereby 148 g of the monomer (X-1) was obtained (yield: 55%).

A scheme of synthesis of the monomer (X-1) is shown below. In the scheme of synthesis below, NEt₃ represents triethylamine.

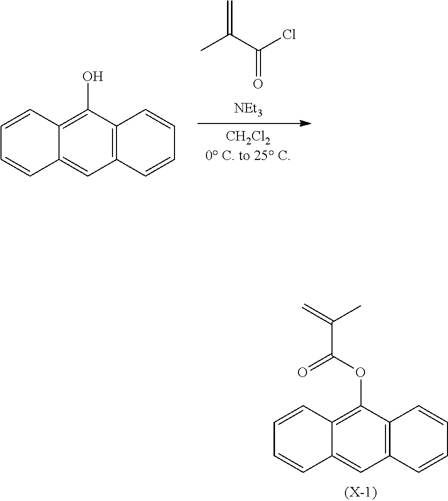

### Synthesis Examples 1-2 to 1-16 and 1-19 to 1-32: Synthesis of Monomers (X-2) to (X-16) and (X-19) to (X-32)

The monomers (X-2) to (X-16) and (X-19) to (X-32) were synthesized in a similar manner to Synthesis Example 1-1 except that the precursors were appropriately selected.

### Synthesis Example 1-17: Synthesis of Monomer (X-17)

In 1,500 mL of dichloromethane, 185 g of anthracene-9-carbonyl chloride was dissolved. After a thus resulting solution was cooled to 0° C., 100 g of 2-hydroxyethyl methacrylate and 117 g of triethylamine were added dropwise at a rate not leading to temperature rise exceeding 25° C. After completion of the dropwise addition, the solution was stirred at 25° C. for 1 hour. Completion of the reaction was followed by quenching with a saturated aqueous ammonium chloride solution, and by extraction with methylene chloride. A residue obtained by concentration in vacuo was subjected to purification by column chromatography, whereby 135 g of the monomer (X-17) was obtained (yield: 53%).

A scheme of synthesis of the monomer (X-17) is shown below. In the scheme of synthesis below, NEt₃ represents triethylamine.

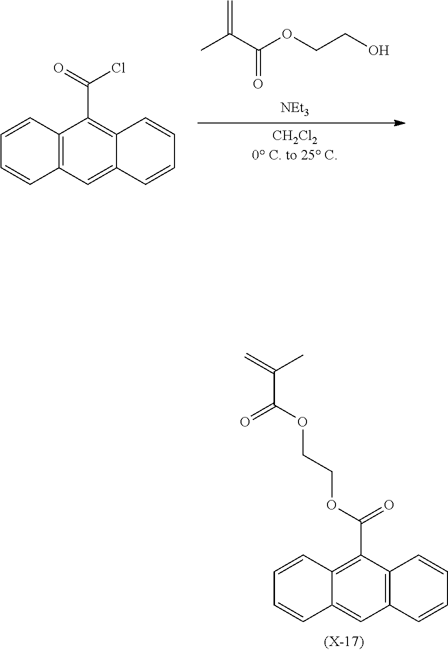

### Synthesis Example 1-18: Synthesis of Monomer (X-18)

The monomer (X-18) was synthesized in a similar manner to Synthesis Example 1-17 except that the precursor was appropriately selected.

### Synthesis of Polymer (A)

According to the following procedure, polymers (A-1) to (A-70) and (CA-1) to (CA-6) as the polymer (A) were synthesized. For synthesis of the polymer (A), the monomers (X-1) to (X-32), and compounds (hereinafter, may be also referred to as “monomers (M-1) to (M-29) and (CX-1) to (CX-3)”) represented by the following formulae (M-1) to (M-29) and (CX-1) to (CX-3) were used. In the following Synthesis Examples, unless otherwise specified particularly, the term “parts by mass” means a value, provided that the total mass of the monomers used was 100 parts by mass, and the term “mol %” means a value, provided that the total mol number of the monomers used was 100 mol %.

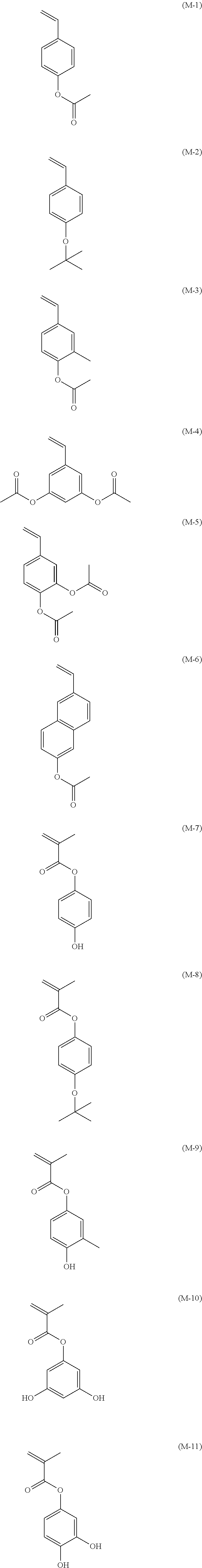

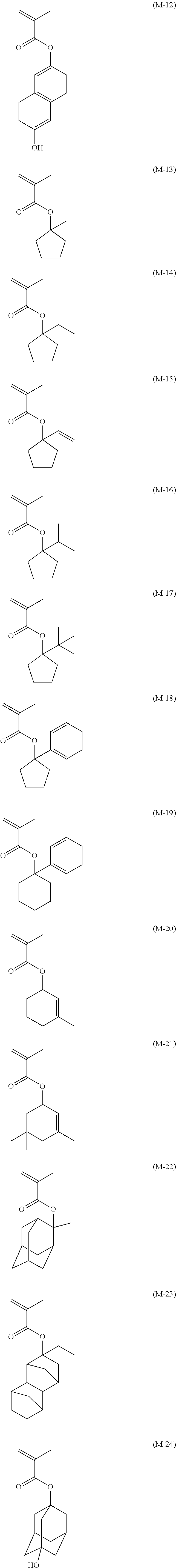

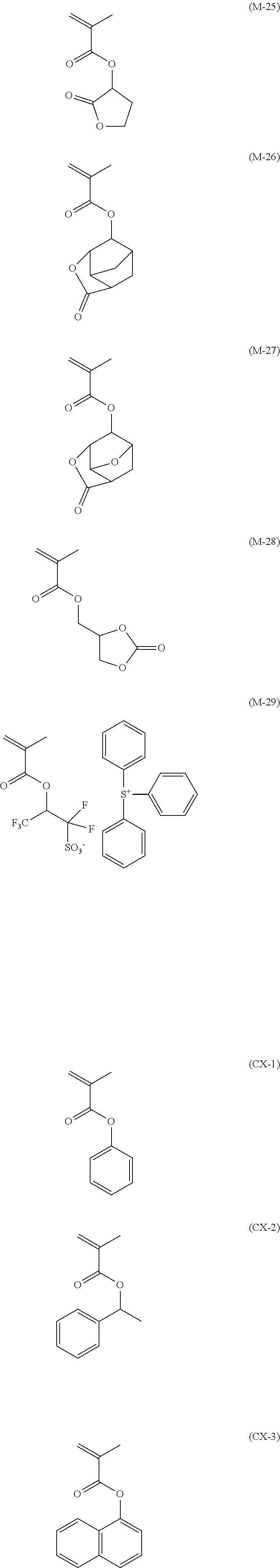

### Synthesis Example 2-1: Synthesis of Polymer (A-1)

The monomer (X-1), the monomer (M-1), and the monomer (M-13) were dissolved in propylene glycol monomethyl ether (200 parts by mass with respect to the total amount of the monomers) such that a molar ratio of the monomers became 10/40/50. Next, thereto was added as an initiator, 6 mol % azobisisobutyronitrile (hereinafter, may be also referred to as “AIBN”), with respect to the total amount of the monomers, to prepare a monomer solution. Meanwhile, propylene glycol monomethyl ether (100 parts by mass with respect to the total amount of the monomers) was charged into an empty reaction vessel and was heated to 85° C. with stirring. Next, the monomer solution prepared as described above was added dropwise to the reaction vessel over 3 hours, and then a thus resulting solution was further heated for 3 hours at 85° C. After completion of the polymerization reaction, the polymerization solution was cooled to room temperature. The polymerization solution thus cooled was charged into hexane (500 parts by mass with respect to the polymerization solution), and a precipitated white powder was filtered off. The white powder obtained by the filtration was washed twice with 100 parts by mass of hexane with respect to the polymerization solution. Thereafter, dissolution in propylene glycol monomethyl ether (300 parts by mass) was allowed again. Next, methanol (500 parts by mass), triethylamine (50 parts by mass), and ultra-pure water (10 parts by mass) were added to a resulting solution, and a hydrolysis reaction was performed at 70° C. for 6 hours with stirring. After completion of the reaction, the remaining solvent was distilled away. A solid thus obtained was dissolved in acetone (100 parts by mass). The solution was added dropwise to 500 parts by mass of water to permit coagulation of the resin, and a solid thus obtained was filtered off. Drying at 50° C. for 12 hours gave a white powdery polymer (A-1). The Mw of the polymer (A-1) was 7,900, and the Mw/Mn was 1.6.

### Synthesis Examples 2-2 to 2-64 and 2-71 to 76: Synthesis of Polymers (A-2) to (A-64) and (CA-1) to (CA-6)

The polymers (A-2) to (A-64) and (CA-1) to (CA-6) were synthesized in a similar manner to Synthesis Example 2-1 except that monomers of the type and the using amount shown in Table 1 below were used.

### Synthesis Examples 2-65 to 2-69: Synthesis of Polymers (A-65) to (A-69)

The polymers (A-65) to (A-69) were synthesized in a similar manner to Synthesis Example 2-3 except that the amount of the initiator was appropriately changed.

### Synthesis Example 2-70: Synthesis of Polymer (A-70)

The monomer (X-1), the monomer (M-7), the monomer (M-13), and the monomer (M-29) were dissolved in 2-butanone (200 parts by mass with respect to the total amount of the monomers) such that a molar ratio of the monomers became 30/10/50/10. Thereto was added as an initiator, 6 mol % AIBN, with respect to the total amount of the monomers, to prepare a monomer solution. Meanwhile, 2-butanone (100 parts by mass) was charged into an empty reaction vessel and was heated to 80° C. with stirring. Next, the monomer solution prepared as described above was added dropwise to the reaction vessel over 3 hours, and then a thus resulting solution was further heated for 3 hours at 80° C. After completion of the polymerization reaction, the polymerization solution was cooled to room temperature. The polymerization solution thus cooled was charged into methanol (2,000 parts by mass with respect to the polymerization solution), and a precipitated white powder was filtered off. A solid thus obtained was dissolved in acetone (100 parts by mass). The solution was added dropwise to 500 parts by mass of water, and a solid obtained by coagulation was filtered off. Drying at 50° C. for 12 hours gave a white powdery polymer (A-70). The Mw of the polymer (A-70) was 8,400, and the Mw/Mn was 1.7.

The type and the proportion in use, and the Mw and the Mw/Mn of the monomer that gives each structural unit of the polymers (A) obtained in Synthesis Examples 2-1 to 2-76 are shown in Table 1 below. It is to be noted that in Table 1 below, “-” indicates that the corresponding component was not used.

TABLE 1

| | | Monomer that | | Monomer that | | Monomer that | | Monomer that | | | |
|---|---|---|---|---|---|---|---|---|---|---|---|
| | | gives structural | | gives structural | | gives structural | | gives other | | | |
| | | unit (I) | | unit (II) | | unit (III) | | structural unit | | | |
| | | | using | | using | | using | | using | | |
| | | | amount | | amount | | amount | | amount | Physical | |
| | (A) | | (% by | | (% by | | (% by | | (% by | property values | |
| | Polymer | type | mole) | type | mole) | type | mole) | type | mole) | Mw | Mw/Mn |
| Synthesis | A-1 | X-1 | 10 | M-13 | 50 | M-1 | 40 | — | — | 7900 | 1.6 |
| Example | | | | | | | | | | | |
| 2-1 | | | | | | | | | | | |
| Synthesis | A-2 | X-1 | 20 | M-13 | 50 | M-1 | 30 | — | — | 8000 | 1.6 |
| Example | | | | | | | | | | | |
| 2-2 | | | | | | | | | | | |
| Synthesis | A-3 | X-1 | 30 | M-13 | 50 | M-1 | 20 | — | — | 8200 | 1.6 |
| Example | | | | | | | | | | | |
| 2-3 | | | | | | | | | | | |
| Synthesis | A-4 | X-19 | 40 | — | — | M-1 | 60 | — | — | 7600 | 1.5 |
| Example | | | | | | | | | | | |
| 2-4 | | | | | | | | | | | |
| Synthesis | A-5 | X-19 | 50 | — | — | M-1 | 50 | — | — | 7800 | 1.6 |
| Example | | | | | | | | | | | |
| 2-5 | | | | | | | | | | | |
| Synthesis | A-6 | X-19 | 60 | — | — | M-1 | 40 | — | — | 8100 | 1.5 |
| Example | | | | | | | | | | | |
| 2-6 | | | | | | | | | | | |
| Synthesis | A-7 | X-2 | 30 | M-13 | 50 | M-1 | 20 | — | — | 7700 | 1.6 |
| Example | | | | | | | | | | | |
| 2-7 | | | | | | | | | | | |
| Synthesis | A-8 | X-3 | 30 | M-13 | 50 | M-1 | 20 | — | — | 7500 | 1.5 |
| Example | | | | | | | | | | | |
| 2-8 | | | | | | | | | | | |
| Synthesis | A-9 | X-4 | 30 | M-13 | 50 | M-1 | 20 | — | — | 8100 | 1.7 |
| Example | | | | | | | | | | | |
| 2-9 | | | | | | | | | | | |
| Synthesis | A-10 | X-5 | 30 | M-13 | 50 | M-1 | 20 | — | — | 7600 | 1.6 |
| Example | | | | | | | | | | | |
| 2-10 | | | | | | | | | | | |
| Synthesis | A-11 | X-6 | 30 | M-13 | 50 | M-1 | 20 | — | — | 7600 | 1.5 |
| Example | | | | | | | | | | | |
| 2-11 | | | | | | | | | | | |
| Synthesis | A-12 | X-7 | 30 | M-13 | 50 | M-1 | 20 | — | — | 8200 | 1.4 |
| Example | | | | | | | | | | | |
| 2-12 | | | | | | | | | | | |
| Synthesis | A-13 | X-8 | 30 | M-13 | 50 | M-1 | 20 | — | — | 7000 | 1.7 |
| Example | | | | | | | | | | | |
| 2-13 | | | | | | | | | | | |
| Synthesis | A-14 | X-9 | 30 | M-13 | 50 | M-1 | 20 | — | — | 7400 | 1.6 |
| Example | | | | | | | | | | | |
| 2-14 | | | | | | | | | | | |
| Synthesis | A-15 | X-10 | 30 | M-13 | 50 | M-1 | 20 | — | — | 7700 | 1.6 |
| Example | | | | | | | | | | | |
| 2-15 | | | | | | | | | | | |
| Synthesis | A-16 | X-11 | 30 | M-13 | 50 | M-1 | 20 | — | — | 7300 | 1.5 |
| Example | | | | | | | | | | | |
| 2-16 | | | | | | | | | | | |
| Synthesis | A-17 | X-12 | 30 | M-13 | 50 | M-1 | 20 | — | — | 8200 | 1.5 |
| Example | | | | | | | | | | | |
| 2-17 | | | | | | | | | | | |
| Synthesis | A-18 | X-13 | 30 | M-13 | 50 | M-1 | 20 | — | — | 7600 | 1.6 |
| Example | | | | | | | | | | | |
| 2-18 | | | | | | | | | | | |
| Synthesis | A-19 | X-14 | 30 | M-13 | 50 | M-1 | 20 | — | — | 7600 | 1.6 |
| Example | | | | | | | | | | | |
| 2-19 | | | | | | | | | | | |
| Synthesis | A-20 | X-15 | 30 | M-13 | 50 | M-1 | 20 | — | — | 7800 | 1.5 |
| Example | | | | | | | | | | | |
| 2-20 | | | | | | | | | | | |
| Synthesis | A-21 | X-16 | 30 | M-13 | 50 | M-1 | 20 | — | — | 7800 | 1.5 |
| Example | | | | | | | | | | | |
| 2-21 | | | | | | | | | | | |
| Synthesis | A-22 | X-17 | 30 | M-13 | 50 | M-1 | 20 | — | — | 7100 | 1.4 |
| Example | | | | | | | | | | | |
| 2-22 | | | | | | | | | | | |
| Synthesis | A-23 | X-18 | 30 | M-13 | 50 | M-1 | 20 | — | — | 7400 | 1.6 |
| Example | | | | | | | | | | | |
| 2-23 | | | | | | | | | | | |
| Synthesis | A-24 | X-20 | 50 | — | — | M-1 | 50 | — | — | 7700 | 1.6 |
| Example | | | | | | | | | | | |
| 2-24 | | | | | | | | | | | |
| Synthesis | A-25 | X-21 | 50 | — | — | M-1 | 50 | — | — | 7500 | 1.5 |
| Example | | | | | | | | | | | |
| 2-25 | | | | | | | | | | | |
| Synthesis | A-26 | X-22 | 50 | — | — | M-1 | 50 | — | — | 8100 | 1.6 |
| Example | | | | | | | | | | | |
| 2-26 | | | | | | | | | | | |
| Synthesis | A-27 | X-23 | 50 | — | — | M-1 | 50 | — | — | 7600 | 1.5 |
| Example | | | | | | | | | | | |
| 2-27 | | | | | | | | | | | |
| Synthesis | A-28 | X-24 | 50 | — | — | M-1 | 50 | — | — | 7900 | 1.6 |
| Example | | | | | | | | | | | |
| 2-28 | | | | | | | | | | | |
| Synthesis | A-29 | X-25 | 50 | — | — | M-1 | 50 | — | — | 7600 | 1.5 |
| Example | | | | | | | | | | | |
| 2-29 | | | | | | | | | | | |
| Synthesis | A-30 | X-26 | 50 | — | — | M-1 | 50 | — | — | 7600 | 1.7 |
| Example | | | | | | | | | | | |
| 2-30 | | | | | | | | | | | |
| Synthesis | A-31 | X-27 | 50 | — | — | M-1 | 50 | — | — | 7800 | 1.6 |
| Example | | | | | | | | | | | |
| 2-31 | | | | | | | | | | | |
| Synthesis | A-32 | X-28 | 50 | — | — | M-1 | 50 | — | — | 7800 | 1.5 |
| Example | | | | | | | | | | | |
| 2-32 | | | | | | | | | | | |
| Synthesis | A-33 | X-29 | 50 | — | — | M-1 | 50 | — | — | 7100 | 1.6 |
| Example | | | | | | | | | | | |
| 2-33 | | | | | | | | | | | |
| Synthesis | A-34 | X-30 | 50 | — | — | M-1 | 50 | — | — | 7400 | 1.5 |
| Example | | | | | | | | | | | |
| 2-34 | | | | | | | | | | | |
| Synthesis | A-35 | X-31 | 50 | — | — | M-1 | 50 | — | — | 7700 | 1.6 |
| Example | | | | | | | | | | | |
| 2-35 | | | | | | | | | | | |
| Synthesis | A-36 | X-32 | 50 | — | — | M-1 | 50 | — | — | 7800 | 1.6 |
| Example | | | | | | | | | | | |
| 2-36 | | | | | | | | | | | |
| Synthesis | A-37 | X-33 | 50 | — | — | M-1 | 50 | — | — | 8100 | 1.6 |
| Example | | | | | | | | | | | |
| 2-37 | | | | | | | | | | | |
| Synthesis | A-38 | X-34 | 50 | — | — | M-1 | 50 | — | — | 8200 | 1.5 |
| Example | | | | | | | | | | | |
| 2-38 | | | | | | | | | | | |
| Synthesis | A-39 | X-9 | 30 | M-13 | 50 | M-1/ | 10/10 | — | — | 8300 | 1.6 |
| Example | | | | | | M-2 | | | | | |
| 2-39 | | | | | | | | | | | |
| Synthesis | A-40 | X-9 | 30 | M-13 | 50 | M-1/ | 10/10 | — | — | 7500 | 1.5 |
| Example | | | | | | M-3 | | | | | |
| 2-40 | | | | | | | | | | | |
| Synthesis | A-41 | X-9 | 30 | M-13 | 50 | M-1/ | 10/10 | — | — | 7100 | 1.6 |
| Example | | | | | | M-4 | | | | | |
| 2-41 | | | | | | | | | | | |
| Synthesis | A-42 | X-9 | 30 | M-13 | 50 | M-1/ | 10/10 | — | — | 8200 | 1.6 |
| Example | | | | | | M-5 | | | | | |
| 2-42 | | | | | | | | | | | |
| Synthesis | A-43 | X-9 | 30 | M-13 | 50 | M-1/ | 10/10 | — | — | 7900 | 1.5 |
| Example | | | | | | M-6 | | | | | |
| 2-43 | | | | | | | | | | | |
| Synthesis | A-44 | X-9 | 30 | M-13 | 50 | M-1/ | 10/10 | — | — | 7100 | 1.5 |
| Example | | | | | | M-7 | | | | | |
| 2-44 | | | | | | | | | | | |
| Synthesis | A-45 | X-9 | 30 | M-13 | 50 | M-1/ | 10/10 | — | — | 7400 | 1.5 |
| Example | | | | | | M-8 | | | | | |
| 2-45 | | | | | | | | | | | |
| Synthesis | A-46 | X-9 | 30 | M-13 | 50 | M-1/ | 10/10 | — | — | 770 | 1.7 |
| Example | | | | | | M-9 | | | | | |
| 2-46 | | | | | | | | | | | |
| Synthesis | A-47 | X-9 | 30 | M-13 | 50 | M-1/ | 10/10 | — | — | 7800 | 1.6 |
| Example | | | | | | M-10 | | | | | |
| 2-47 | | | | | | | | | | | |
| Synthesis | A-48 | X-9 | 30 | M-13 | 50 | M-1/ | 10/10 | — | — | 8100 | 1.6 |
| Example | | | | | | M-11 | | | | | |
| 2-48 | | | | | | | | | | | |
| Synthesis | A-49 | X-9 | 30 | M-13 | 50 | M-1/ | 10/10 | — | — | 8300 | 1.5 |
| Example | | | | | | M-12 | | | | | |
| 2-49 | | | | | | | | | | | |
| Synthesis | A-50 | X-9 | 30 | M-14 | 50 | M-1 | 20 | — | — | 7400 | 1.5 |
| Example | | | | | | | | | | | |
| 2-50 | | | | | | | | | | | |
| Synthesis | A-51 | X-9 | 30 | M-15 | 50 | M-1 | 20 | — | — | 7600 | 1.6 |
| Example | | | | | | | | | | | |
| 2-51 | | | | | | | | | | | |
| Synthesis | A-52 | X-9 | 30 | M-16 | 50 | M-1 | 20 | — | — | 7300 | 1.5 |
| Example | | | | | | | | | | | |
| 2-52 | | | | | | | | | | | |
| Synthesis | A-53 | X-9 | 30 | M-17 | 50 | M-1 | 20 | — | — | 8200 | 1.7 |
| Example | | | | | | | | | | | |
| 2-53 | | | | | | | | | | | |
| Synthesis | A-54 | X-9 | 30 | M-18 | 50 | M-1 | 20 | — | — | 7300 | 1.6 |
| Example | | | | | | | | | | | |
| 2-54 | | | | | | | | | | | |
| Synthesis | A-55 | X-9 | 30 | M-19 | 50 | M-1 | 20 | — | — | 8200 | 1.5 |
| Example | | | | | | | | | | | |
| 2-55 | | | | | | | | | | | |
| Synthesis | A-56 | X-9 | 30 | M-20 | 50 | M-1 | 20 | — | — | 7600 | 1.6 |
| Example | | | | | | | | | | | |
| 2-56 | | | | | | | | | | | |
| Synthesis | A-57 | X-9 | 30 | M-21 | 50 | M-1 | 20 | — | — | 8300 | 1.5 |
| Example | | | | | | | | | | | |
| 2-57 | | | | | | | | | | | |
| Synthesis | A-58 | X-9 | 30 | M-22 | 50 | M-1 | 20 | — | — | 7500 | 1.6 |
| Example | | | | | | | | | | | |
| 2-58 | | | | | | | | | | | |
| Synthesis | A-59 | X-9 | 30 | M-23 | 50 | M-1 | 20 | — | — | 7100 | 1.6 |
| Example | | | | | | | | | | | |
| 2-59 | | | | | | | | | | | |
| Synthesis | A-60 | X-9 | 30 | M-13 | 50 | M-1 | 10 | M-24 | 10 | 8200 | 1.6 |
| Example | | | | | | | | | | | |
| 2-60 | | | | | | | | | | | |
| Synthesis | A-61 | X-9 | 30 | M-13 | 50 | M-1 | 10 | M-25 | 10 | 7900 | 1.6 |
| Example | | | | | | | | | | | |
| 2-61 | | | | | | | | | | | |
| Synthesis | A-62 | X-9 | 30 | M-13 | 50 | M-1 | 10 | M-26 | 10 | 7100 | 1.5 |
| Example | | | | | | | | | | | |
| 2-62 | | | | | | | | | | | |
| Synthesis | A-63 | X-9 | 30 | M-13 | 50 | M-1 | 10 | M-27 | 10 | 7400 | 1.5 |
| Example | | | | | | | | | | | |
| 2-63 | | | | | | | | | | | |
| Synthesis | A-64 | X-9 | 30 | M-13 | 50 | M-1 | 10 | M-28 | 10 | 7700 | 1.6 |
| Example | | | | | | | | | | | |
| 2-64 | | | | | | | | | | | |
| Synthesis | A-65 | X-1 | 30 | M-13 | 50 | M-1 | 20 | — | — | 18700 | 1.9 |
| Example | | | | | | | | | | | |
| 2-65 | | | | | | | | | | | |
| Synthesis | A-66 | X-1 | 30 | M-13 | 50 | M-1 | 20 | — | — | 16500 | 1.7 |
| Example | | | | | | | | | | | |
| 2-66 | | | | | | | | | | | |
| Synthesis | A-67 | X-1 | 30 | M-13 | 50 | M-1 | 20 | — | — | 12100 | 1.7 |
| Example | | | | | | | | | | | |
| 2-67 | | | | | | | | | | | |
| Synthesis | A-68 | X-1 | 30 | M-13 | 50 | M-1 | 20 | — | — | 5000 | 1.4 |
| Example | | | | | | | | | | | |
| 2-68 | | | | | | | | | | | |
| Synthesis | A-69 | X-1 | 30 | M-13 | 50 | M-1 | 20 | — | — | 3100 | 1.4 |
| Example | | | | | | | | | | | |
| 2-69 | | | | | | | | | | | |
| Synthesis | A-70 | X-1 | 30 | M-13 | 50 | M-7 | 10 | M-29 | 10 | 8400 | 1.7 |
| Example | | | | | | | | | | | |
| 2-70 | | | | | | | | | | | |
| Synthesis | CA-1 | — | — | M-13 | 50 | M-1 | 50 | — | — | 7500 | 1.5 |
| Example | | | | | | | | | | | |
| 2-71 | | | | | | | | | | | |
| Synthesis | CA-2 | — | — | M-14 | 50 | M-1 | 50 | — | — | 7100 | 1.5 |
| Example | | | | | | | | | | | |
| 2-72 | | | | | | | | | | | |
| Synthesis | CA-3 | — | — | M-15 | 50 | M-1 | 50 | — | — | 7600 | 1.6 |
| Example | | | | | | | | | | | |
| 2-73 | | | | | | | | | | | |
| Synthesis | CA-4 | CX-1 | 30 | M-13 | 50 | M-1 | 20 | — | — | 7200 | 1.6 |
| Example | | | | | | | | | | | |
| 2-74 | | | | | | | | | | | |
| Synthesis | CA-5 | CX-2 | 30 | M-13 | 50 | M-1 | 20 | — | — | 7400 | 1.5 |
| Example | | | | | | | | | | | |
| 2-75 | | | | | | | | | | | |
| Synthesis | CA-6 | CX-3 | 30 | M-13 | 50 | M-1 | 20 | — | — | 7400 | 1.5 |
| Example | | | | | | | | | | | |
| 2-76 | | | | | | | | | | | |

### Preparation of Radiation-Sensitive Resin Composition

The acid generating agent (B), the acid diffusion control agent (C), and the organic solvent (D) used in preparation of the radiation-sensitive resin composition are shown below. In the following Examples and Comparative Examples, unless otherwise specified particularly, the term “parts by mass” means a value, provided that the mass of the polymer (A) used was 100 parts by mass, and the term “mol %” means a value, provided that the mol number of the acid generating agent (B) used was 100 mol %.

### (B) Acid Generating Agent

Compounds (hereinafter, may be also referred to as “acid generating agents (B-1) to (B-18)”) represented by the following formulae (B-1) to (B-18) were used as the acid generating agent (B).

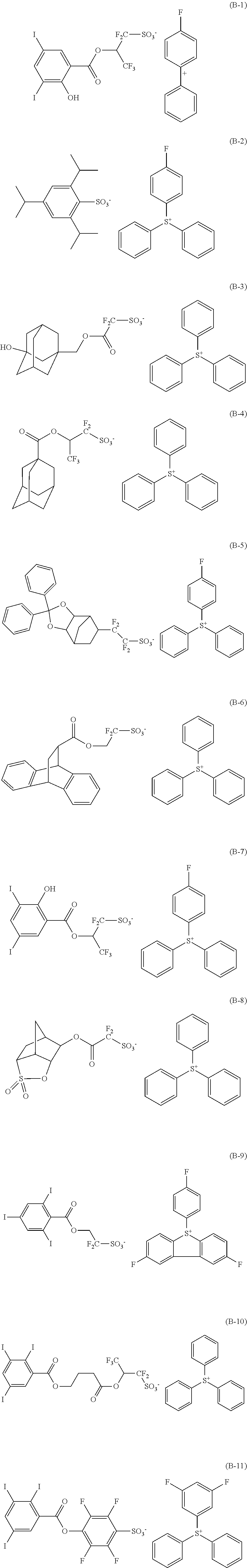

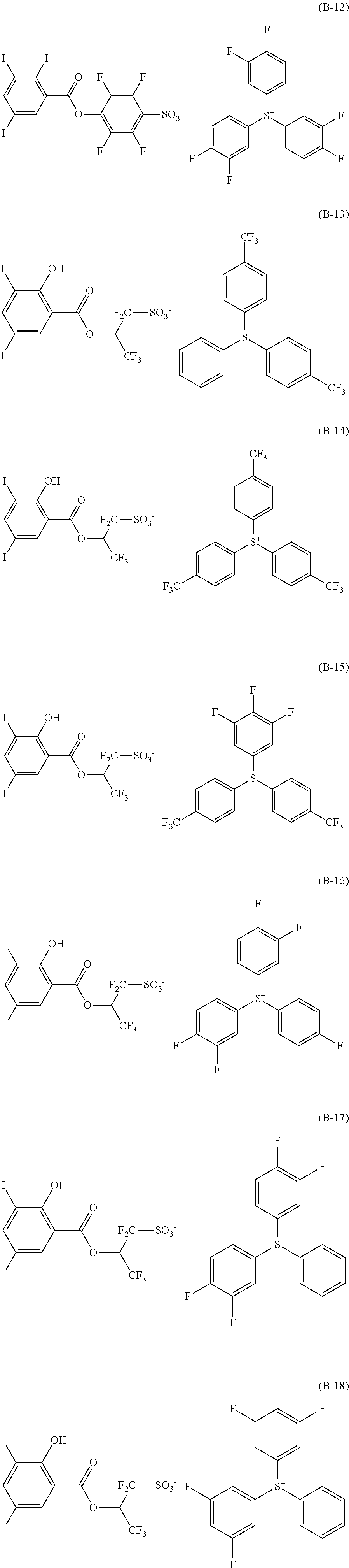

### (C) Acid Diffusion Control Agent

Compounds (hereinafter, may be also referred to as “acid diffusion control agents (C-1) to (C-12) and (CC-1)”) represented by the following formulae (C-1) to (C-12) and (CC-1) were used as the acid diffusion control agent (C). It is to be noted that the acid diffusion control agent (CC-1) does not fall under the category of the “acid diffusion control agent having a monovalent radiation-sensitive onium cation and a monovalent organic acid anion”.

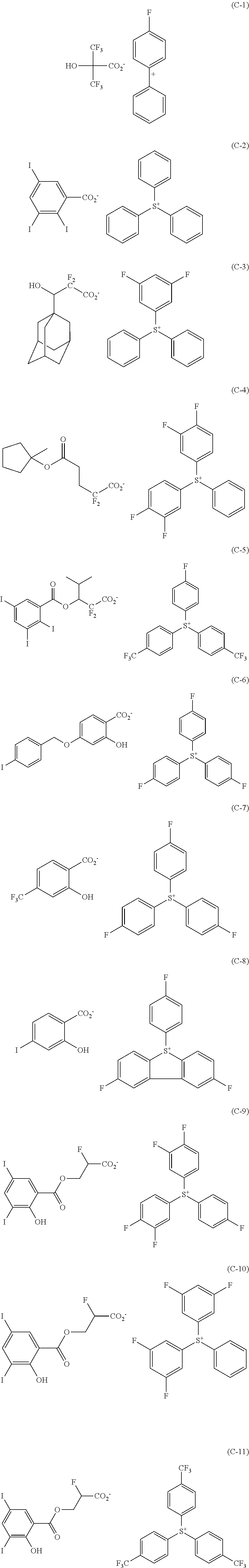

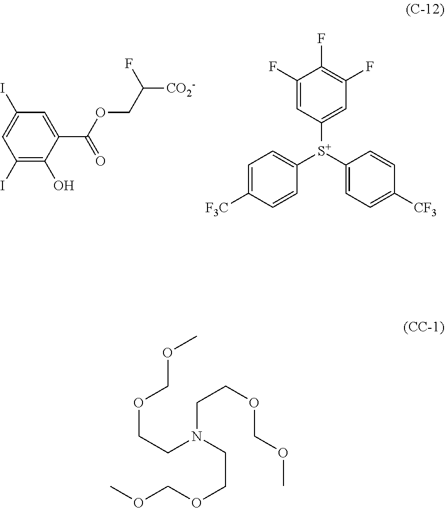

### (D) Organic Solvent

The following organic solvents were used as the organic solvent (D).
(D-1): propylene glycol monomethyl ether acetate
(D-2): propylene glycol monomethyl ether

### Example 1: Preparation of Radiation-Sensitive Resin Composition (R-1)

100 parts by mass of (A-1) as the polymer (A), 20 parts by mass of (B-1) as the acid generating agent (B), (C-1) as the acid diffusion control agent (C) in an amount of 20 mol % with respect to (B-1), and 4,800 parts by mass of (D-1) and 2,000 parts by mass of (D-2) as the organic solvent (D) were admixed. A mix liquid thus obtained was filtered through a membrane filter having a pore size of 0.20 μm, whereby a radiation-sensitive resin composition (R-1) was prepared.

### Examples 2 to 98 and Comparative Examples 1 to 7: Preparation of Radiation-Sensitive Resin Compositions (R-2) to (R-98) and (CR-1) to (CR-7)

Radiation-sensitive resin compositions (R-2) to (R-98) and (CR-1) to (CR-7) were prepared in a similar manner to Example 1 except that each component of the type and in the content shown in Table 2 and Table 3 below was used.

### Formation of Resist Pattern

By using a spin coater (“CLEAN TRACK ACT 12,” available from Tokyo Electron Limited), the radiation-sensitive resin composition prepared as described above was applied on a 12-inch silicon wafer surface provided with an underlayer film (“AL412” available from Brewer Science, Inc.) having an average thickness of 20 nm formed thereon. A resist film having an average thickness of 50 nm was formed through prebaking (PB) carried out at 130° C. for 60 sec, followed by cooling at 23° C. for 30 sec. Next, this resist film was irradiated with EUV light by using an EUV scanner (“NXE3300” available from ASML Co.: NA=0.33, irradiation conditions: Conventional s=0.89, mask: imec DEFECT32FFR02). After the irradiation, the resist film was subjected to post exposure baking (PEB) at 110° C. for 60 sec. Subsequently, development was performed using a 2.38% by mass aqueous TMAH solution as an alkaline developer solution at 23° C. for 30 sec to form a positive-tone, 32 nm line-and-space pattern.

### Evaluations

Each resist pattern formed as described above was evaluated on the sensitivity, the LWR performance, and the process window in accordance with the following methods. Line-width measurement of the resist pattern was performed using a scanning electron microscope (“CG-4100” available from Hitachi High-Tech Corporation). The results of the evaluations are shown in Table 2 and Table 3 below.

### Sensitivity

An exposure dose at which a 32 nm line-and-space pattern was formed in the aforementioned Formation of Resist Pattern was defined as an optimum exposure dose, and this optimum exposure dose was adopted as Eop (units: mJ/cm²). The Eop value being smaller indicates more favorable sensitivity.

### LWR Performance

The resist pattern formed as described above was observed from above using the scanning electron microscope. Line widths were measured at arbitrary 50 sites in total, and then a 3 Sigma value was determined from distribution of the measurement values and this value was defined as LWR (unit: nm). The LWR value being smaller indicates more favorable LWR performance.

### Process Window

Using a mask to form 32 nm line-and-space (1L/1S), patterns were formed with exposure doses, from low to high. In general, defects such as bridging between patterns are found in cases at low exposure doses, and pattern collapse is found in cases at high exposure doses. The difference between the maximum value and the minimum value of resist dimensions, without these defects being found, was defined as a CD (Critical Dimension) margin (unit: nm). The CD margin value being larger indicates a broader process window being more favorable.

TABLE 2

| | | | | | | (C) Acid diffusion | |
|---|---|---|---|---|---|---|---|
| | Radiation- | (A) Polymer | | (B) Acid generating agent | | control agent | |
| | sensitive resin | | content (parts | | content (parts | | content (% by |
| | composition | type | by mass) | type | by mass) | type | mole) |
| Example 1 | R-1 | A-1 | 100 | B-1 | 20 | C-1 | 20 |
| Example 2 | R-2 | A-2 | 100 | B-1 | 20 | C-1 | 20 |
| Example 3 | R-3 | A-3 | 100 | B-1 | 20 | C-1 | 20 |
| Example 4 | R-4 | A-4 | 100 | B-1 | 20 | C-1 | 20 |
| Example 5 | R-5 | A-5 | 100 | B-1 | 20 | C-1 | 20 |
| Example 6 | R-6 | A-6 | 100 | B-1 | 20 | C-1 | 20 |
| Example 7 | R-7 | A-7 | 100 | B-1 | 20 | C-1 | 20 |
| Example 8 | R-8 | A-8 | 100 | B-1 | 20 | C-1 | 20 |
| Example 9 | R-9 | A-9 | 100 | B-1 | 20 | C-1 | 20 |
| Example 10 | R-10 | A-10 | 100 | B-1 | 20 | C-1 | 20 |
| Example 11 | R-11 | A-11 | 100 | B-1 | 20 | C-1 | 20 |
| Example 12 | R-12 | A-12 | 100 | B-1 | 20 | C-1 | 20 |
| Example 13 | R-13 | A-13 | 100 | B-1 | 20 | C-1 | 20 |
| Example 14 | R-14 | A-14 | 100 | B-1 | 20 | C-1 | 20 |
| Example 15 | R-15 | A-15 | 100 | B-1 | 20 | C-1 | 20 |
| Example 16 | R-16 | A-16 | 100 | B-1 | 20 | C-1 | 20 |
| Example 17 | R-17 | A-17 | 100 | B-1 | 20 | C-1 | 20 |
| Example 18 | R-18 | A-18 | 100 | B-1 | 20 | C-1 | 20 |
| Example 19 | R-19 | A-19 | 100 | B-1 | 20 | C-1 | 20 |
| Example 20 | R-20 | A-20 | 100 | B-1 | 20 | C-1 | 20 |
| Example 21 | R-21 | A-21 | 100 | B-1 | 20 | C-1 | 20 |
| Example 22 | R-22 | A-22 | 100 | B-1 | 20 | C-1 | 20 |
| Example 23 | R-23 | A-23 | 100 | B-1 | 20 | C-1 | 20 |
| Example 24 | R-24 | A-24 | 100 | B-1 | 20 | C-1 | 20 |
| Example 25 | R-25 | A-25 | 100 | B-1 | 20 | C-1 | 20 |
| Example 26 | R-26 | A-26 | 100 | B-1 | 20 | C-1 | 20 |
| Example 27 | R-27 | A-27 | 100 | B-1 | 20 | C-1 | 20 |
| Example 28 | R-28 | A-28 | 100 | B-1 | 20 | C-1 | 20 |
| Example 29 | R-29 | A-29 | 100 | B-1 | 20 | C-1 | 20 |
| Example 30 | R-30 | A-30 | 100 | B-1 | 20 | C-1 | 20 |
| Example 31 | R-31 | A-31 | 100 | B-1 | 20 | C-1 | 20 |
| Example 32 | R-32 | A-32 | 100 | B-1 | 20 | C-1 | 20 |
| Example 33 | R-33 | A-33 | 100 | B-1 | 20 | C-1 | 20 |
| Example 34 | R-34 | A-34 | 100 | B-1 | 20 | C-1 | 20 |
| Example 35 | R-35 | A-35 | 100 | B-1 | 20 | C-1 | 20 |
| Example 36 | R-36 | A-36 | 100 | B-1 | 20 | C-1 | 20 |
| Example 37 | R-37 | A-37 | 100 | B-1 | 20 | C-1 | 20 |
| Example 38 | R-38 | A-38 | 100 | B-1 | 20 | C-1 | 20 |
| Example 39 | R-39 | A-39 | 100 | B-1 | 20 | C-1 | 20 |
| Example 40 | R-40 | A-40 | 100 | B-1 | 20 | C-1 | 20 |
| Example 41 | R-41 | A-41 | 100 | B-1 | 20 | C-1 | 20 |
| Example 42 | R-42 | A-42 | 100 | B-1 | 20 | C-1 | 20 |
| Example 43 | R-43 | A-43 | 100 | B-1 | 20 | C-1 | 20 |
| Example 44 | R-44 | A-44 | 100 | B-1 | 20 | C-1 | 20 |
| Example 45 | R-45 | A-45 | 100 | B-1 | 20 | C-1 | 20 |
| Example 46 | R-46 | A-46 | 100 | B-1 | 20 | C-1 | 20 |
| Example 47 | R-47 | A-47 | 100 | B-1 | 20 | C-1 | 20 |
| Example 48 | R-48 | A-48 | 100 | B-1 | 20 | C-1 | 20 |
| Example 49 | R-49 | A-49 | 100 | B-1 | 20 | C-1 | 20 |
| Example 50 | R-50 | A-50 | 100 | B-1 | 20 | C-1 | 20 |
| Example 51 | R-51 | A-51 | 100 | B-1 | 20 | C-1 | 20 |
| Example 52 | R-52 | A-52 | 100 | B-1 | 20 | C-1 | 20 |
| Example 53 | R-53 | A-53 | 100 | B-1 | 20 | C-1 | 20 |
| Example 54 | R-54 | A-54 | 100 | B-1 | 20 | C-1 | 20 |
| Example 55 | R-55 | A-55 | 100 | B-1 | 20 | C-1 | 20 |
| Example 56 | R-56 | A-56 | 100 | B-1 | 20 | C-1 | 20 |
| Example 57 | R-57 | A-57 | 100 | B-1 | 20 | C-1 | 20 |
| Example 58 | R-58 | A-58 | 100 | B-1 | 20 | C-1 | 20 |
| Example 59 | R-59 | A-59 | 100 | B-1 | 20 | C-1 | 20 |
| Example 60 | R-60 | A-60 | 100 | B-1 | 20 | C-1 | 20 |
| Example 61 | R-61 | A-61 | 100 | B-1 | 20 | C-1 | 20 |
| Example 62 | R-62 | A-62 | 100 | B-1 | 20 | C-1 | 20 |
| Example 63 | R-63 | A-63 | 100 | B-1 | 20 | C-1 | 20 |
| Example 64 | R-64 | A-64 | 100 | B-1 | 20 | C-1 | 20 |
| Example 65 | R-65 | A-65 | 100 | B-1 | 20 | C-1 | 20 |
| Example 66 | R-66 | A-66 | 100 | B-1 | 20 | C-1 | 20 |
| Example 67 | R-67 | A-67 | 100 | B-1 | 20 | C-1 | 20 |
| Example 68 | R-68 | A-68 | 100 | B-1 | 20 | C-1 | 20 |
| Example 69 | R-69 | A-69 | 100 | B-1 | 20 | C-1 | 20 |
| Example 70 | R-70 | A-70 | 100 | B-1 | 20 | C-1 | 20 |

| | | (D) Solvent | | | | |
|---|---|---|---|---|---|---|
| | Radiation- | | content | Results of evaluations | | |
| | sensitive resin | | (parts by | Eop | LWR | CD margin |
| | composition | type | mass) | (mJ/cm²) | (nm) | (nm) |
| Example 1 | R-1 | D-1/D-2 | 4800/2000 | 24 | 3.8 | 32 |
| Example 2 | R-2 | D-1/D-2 | 4800/2000 | 26 | 3.5 | 35 |
| Example 3 | R-3 | D-1/D-2 | 4800/2000 | 28 | 3.2 | 37 |
| Example 4 | R-4 | D-1/D-2 | 4800/2000 | 27 | 3.1 | 35 |
| Example 5 | R-5 | D-1/D-2 | 4800/2000 | 29 | 3.2 | 37 |
| Example 6 | R-6 | D-1/D-2 | 4800/2000 | 30 | 3.3 | 38 |
| Example 7 | R-7 | D-1/D-2 | 4800/2000 | 28 | 3.2 | 35 |
| Example 8 | R-8 | D-1/D-2 | 4800/2000 | 29 | 3.5 | 34 |
| Example 9 | R-9 | D-1/D-2 | 4800/2000 | 29 | 3.6 | 35 |
| Example 10 | R-10 | D-1/D-2 | 4800/2000 | 29 | 3.5 | 34 |
| Example 11 | R-11 | D-1/D-2 | 4800/2000 | 29 | 3.6 | 32 |
| Example 12 | R-12 | D-1/D-2 | 4800/2000 | 28 | 3.5 | 33 |
| Example 13 | R-13 | D-1/D-2 | 4800/2000 | 29 | 3.6 | 32 |
| Example 14 | R-14 | D-1/D-2 | 4800/2000 | 26 | 3.2 | 38 |
| Example 15 | R-15 | D-1/D-2 | 4800/2000 | 26 | 3.2 | 37 |
| Example 16 | R-16 | D-1/D-2 | 4800/2000 | 26 | 3.1 | 34 |
| Example 17 | R-17 | D-1/D-2 | 4800/2000 | 25 | 3.1 | 34 |
| Example 18 | R-18 | D-1/D-2 | 4800/2000 | 25 | 3.5 | 35 |
| Example 19 | R-19 | D-1/D-2 | 4800/2000 | 26 | 3.4 | 33 |
| Example 20 | R-20 | D-1/D-2 | 4800/2000 | 24 | 3.3 | 35 |
| Example 21 | R-21 | D-1/D-2 | 4800/2000 | 24 | 3.5 | 33 |
| Example 22 | R-22 | D-1/D-2 | 4800/2000 | 27 | 3.4 | 35 |
| Example 23 | R-23 | D-1/D-2 | 4800/2000 | 25 | 3.3 | 36 |
| Example 24 | R-24 | D-1/D-2 | 4800/2000 | 28 | 3.2 | 37 |
| Example 25 | R-25 | D-1/D-2 | 4800/2000 | 28 | 3.2 | 36 |
| Example 26 | R-26 | D-1/D-2 | 4800/2000 | 27 | 3.2 | 35 |
| Example 27 | R-27 | D-1/D-2 | 4800/2000 | 26 | 3.1 | 33 |
| Example 28 | R-28 | D-1/D-2 | 4800/2000 | 28 | 3.3 | 35 |
| Example 29 | R-29 | D-1/D-2 | 4800/2000 | 27 | 3.5 | 32 |
| Example 30 | R-30 | D-1/D-2 | 4800/2000 | 25 | 3.2 | 37 |
| Example 31 | R-31 | D-1/D-2 | 4800/2000 | 25 | 3.1 | 37 |
| Example 32 | R-32 | D-1/D-2 | 4800/2000 | 24 | 3.1 | 37 |
| Example 33 | R-33 | D-1/D-2 | 4800/2000 | 24 | 3.1 | 36 |
| Example 34 | R-34 | D-1/D-2 | 4800/2000 | 23 | 3.1 | 35 |
| Example 35 | R-35 | D-1/D-2 | 4800/2000 | 25 | 3.4 | 31 |
| Example 36 | R-36 | D-1/D-2 | 4800/2000 | 24 | 3.5 | 30 |
| Example 37 | R-37 | D-1/D-2 | 4800/2000 | 24 | 3.5 | 32 |
| Example 38 | R-38 | D-1/D-2 | 4800/2000 | 23 | 3.5 | 31 |
| Example 39 | R-39 | D-1/D-2 | 4800/2000 | 28 | 3.1 | 39 |
| Example 40 | R-40 | D-1/D-2 | 4800/2000 | 28 | 3.1 | 39 |
| Example 41 | R-41 | D-1/D-2 | 4800/2000 | 23 | 3.6 | 35 |
| Example 42 | R-42 | D-1/D-2 | 4800/2000 | 23 | 3.5 | 35 |
| Example 43 | R-43 | D-1/D-2 | 4800/2000 | 24 | 3.4 | 36 |
| Example 44 | R-44 | D-1/D-2 | 4800/2000 | 25 | 3.3 | 35 |
| Example 45 | R-45 | D-1/D-2 | 4800/2000 | 27 | 3.2 | 37 |
| Example 46 | R-46 | D-1/D-2 | 4800/2000 | 27 | 3.2 | 38 |
| Example 47 | R-47 | D-1/D-2 | 4800/2000 | 24 | 3.6 | 35 |
| Example 48 | R-48 | D-1/D-2 | 4800/2000 | 24 | 3.6 | 35 |
| Example 49 | R-49 | D-1/D-2 | 4800/2000 | 24 | 3.3 | 35 |
| Example 50 | R-50 | D-1/D-2 | 4800/2000 | 26 | 3.1 | 37 |
| Example 51 | R-51 | D-1/D-2 | 4800/2000 | 26 | 3.1 | 37 |
| Example 52 | R-52 | D-1/D-2 | 4800/2000 | 25 | 3.2 | 37 |
| Example 53 | R-53 | D-1/D-2 | 4800/2000 | 25 | 3.2 | 35 |
| Example 54 | R-54 | D-1/D-2 | 4800/2000 | 24 | 3.2 | 33 |
| Example 55 | R-55 | D-1/D-2 | 4800/2000 | 24 | 3.2 | 35 |
| Example 56 | R-56 | D-1/D-2 | 4800/2000 | 25 | 3.2 | 36 |
| Example 57 | R-57 | D-1/D-2 | 4800/2000 | 24 | 3.2 | 34 |
| Example 58 | R-58 | D-1/D-2 | 4800/2000 | 28 | 3.1 | 38 |
| Example 59 | R-59 | D-1/D-2 | 4800/2000 | 28 | 3.1 | 38 |
| Example 60 | R-60 | D-1/D-2 | 4800/2000 | 28 | 3.1 | 36 |
| Example 61 | R-61 | D-1/D-2 | 4800/2000 | 25 | 3.4 | 37 |
| Example 62 | R-62 | D-1/D-2 | 4800/2000 | 28 | 3.1 | 35 |
| Example 63 | R-63 | D-1/D-2 | 4800/2000 | 26 | 3.1 | 34 |
| Example 64 | R-64 | D-1/D-2 | 4800/2000 | 24 | 3.2 | 31 |
| Example 65 | R-65 | D-1/D-2 | 4800/2000 | 30 | 3.3 | 37 |
| Example 66 | R-66 | D-1/D-2 | 4800/2000 | 29 | 3.2 | 37 |
| Example 67 | R-67 | D-1/D-2 | 4800/2000 | 29 | 3.2 | 37 |
| Example 68 | R-68 | D-1/D-2 | 4800/2000 | 28 | 3.1 | 34 |
| Example 69 | R-69 | D-1/D-2 | 4800/2000 | 27 | 3.1 | 33 |
| Example 70 | R-70 | D-1/D-2 | 4800/2000 | 25 | 3.1 | 31 |

TABLE 3

| | | | | (B) Acid | | (C) Acid diffusion | | | |
|---|---|---|---|---|---|---|---|---|---|
| | Radiation- | (A) Polymer | | generating agent | | control agent | | (D) Solvent | |
| | sensitive | | content | | content | | content | | content |
| | resin | | (parts by | | (parts by | | (% by | | (parts by |
| | composition | type | mass) | type | mass) | type | mole) | type | mass) |
| Example 71 | R-71 | A-1 | 100 | B-2 | 20 | C-1 | 20 | D-1/D-2 | 4800/2000 |
| Example 72 | R-72 | A-1 | 100 | B-3 | 20 | C-1 | 20 | D-1/D-2 | 4800/2000 |
| Example 73 | R-73 | A-1 | 100 | B-4 | 20 | C-1 | 20 | D-1/D-2 | 4800/2000 |
| Example 74 | R-74 | A-1 | 100 | B-5 | 20 | C-1 | 20 | D-1/D-2 | 4800/2000 |
| Example 75 | R-75 | A-1 | 100 | B-6 | 20 | C-1 | 20 | D-1/D-2 | 4800/2000 |
| Example 76 | R-76 | A-1 | 100 | B-7 | 20 | C-1 | 20 | D-1/D-2 | 4800/2000 |
| Example 77 | R-77 | A-1 | 100 | B-8 | 20 | C-1 | 20 | D-1/D-2 | 4800/2000 |
| Example 78 | R-78 | A-1 | 100 | B-9 | 20 | C-1 | 20 | D-1/D-2 | 4800/2000 |
| Example 79 | R-79 | A-1 | 100 | B-10 | 20 | C-1 | 20 | D-1/D-2 | 4800/2000 |
| Example 80 | R-80 | A-1 | 100 | B-11 | 20 | C-1 | 20 | D-1/D-2 | 4800/2000 |
| Example 81 | R-81 | A-1 | 100 | B-12 | 20 | C-1 | 20 | D-1/D-2 | 4800/2000 |
| Example 82 | R-82 | A-1 | 100 | B-13 | 20 | C-1 | 20 | D-1/D-2 | 4800/2000 |
| Example 83 | R-83 | A-1 | 100 | B-14 | 20 | C-1 | 20 | D-1/D-2 | 4800/2000 |
| Example 84 | R-84 | A-1 | 100 | B-15 | 20 | C-1 | 20 | D-1/D-2 | 4800/2000 |
| Example 85 | R-85 | A-1 | 100 | B-16 | 20 | C-1 | 20 | D-1/D-2 | 4800/2000 |
| Example 86 | R-86 | A-1 | 100 | B-17 | 20 | C-1 | 20 | D-1/D-2 | 4800/2000 |
| Example 87 | R-87 | A-1 | 100 | B-18 | 20 | C-1 | 20 | D-1/D-2 | 4800/2000 |
| Example 88 | R-88 | A-1 | 100 | B-1 | 20 | C-2 | 20 | D-1/D-2 | 4800/2000 |
| Example 89 | R-89 | A-1 | 100 | B-1 | 20 | C-3 | 20 | D-1/D-2 | 4800/2000 |
| Example 90 | R-90 | A-1 | 100 | B-1 | 20 | C-4 | 20 | D-1/D-2 | 4800/2000 |
| Example 91 | R-91 | A-1 | 100 | B-1 | 20 | C-5 | 20 | D-1/D-2 | 4800/2000 |
| Example 92 | R-92 | A-1 | 100 | B-1 | 20 | C-6 | 20 | D-1/D-2 | 4800/2000 |
| Example 93 | R-93 | A-1 | 100 | B-1 | 20 | C-7 | 20 | D-1/D-2 | 4800/2000 |
| Example 94 | R-94 | A-1 | 100 | B-1 | 20 | C-8 | 20 | D-1/D-2 | 4800/2000 |
| Example 95 | R-95 | A-1 | 100 | B-1 | 20 | C-9 | 20 | D-1/D-2 | 4800/2000 |
| Example 96 | R-96 | A-1 | 100 | B-1 | 20 | C-10 | 20 | D-1/D-2 | 4800/2000 |
| Example 97 | R-97 | A-1 | 100 | B-1 | 20 | C-11 | 20 | D-1/D-2 | 4800/2000 |
| Example 98 | R-98 | A-1 | 100 | B-1 | 20 | C-12 | 20 | D-1/D-2 | 4800/2000 |
| Comparative | CR-1 | CA-1 | 100 | B-1 | 20 | C-1 | 20 | D-1/D-2 | 4800/2000 |
| Example 1 | | | | | | | | | |
| Comparative | CR-2 | CA-2 | 100 | B-1 | 20 | C-1 | 20 | D-1/D-2 | 4800/2000 |
| Example 2 | | | | | | | | | |
| Comparative | CR-3 | CA-3 | 100 | B-1 | 20 | C-1 | 20 | D-1/D-2 | 4800/2000 |
| Example 3 | | | | | | | | | |
| Comparative | CR-4 | CA-4 | 100 | B-1 | 20 | C-1 | 20 | D-1/D-2 | 4800/2000 |
| Example 4 | | | | | | | | | |
| Comparative | CR-5 | CA-5 | 100 | B-1 | 20 | C-1 | 20 | D-1/D-2 | 4800/2000 |
| Example 5 | | | | | | | | | |
| Comparative | CR-6 | CA-6 | 100 | B-1 | 20 | C-1 | 20 | D-1/D-2 | 4800/2000 |
| Example 6 | | | | | | | | | |
| Comparative | CR-7 | A-1 | 100 | B-1 | 20 | CC-1 | 20 | D-1/D-2 | 4800/2000 |
| Example 7 | | | | | | | | | |

| | Radiation- | | | |
|---|---|---|---|---|
| | sensitive | Results of evaluations | | |
| | resin | Eop | LWR | CD margin |
| | composition | (mJ/cm²) | (nm) | (nm) |
| Example 71 | R-71 | 30 | 3.2 | 38 |
| Example 72 | R-72 | 30 | 3.3 | 35 |
| Example 73 | R-73 | 30 | 3.2 | 35 |
| Example 74 | R-74 | 30 | 3.2 | 37 |
| Example 75 | R-75 | 30 | 3.3 | 35 |
| Example 76 | R-76 | 28 | 3.2 | 37 |
| Example 77 | R-77 | 30 | 3.3 | 34 |
| Example 78 | R-78 | 27 | 3.2 | 36 |
| Example 79 | R-79 | 28 | 3.2 | 36 |
| Example 80 | R-80 | 27 | 3.3 | 38 |
| Example 81 | R-81 | 26 | 3.2 | 36 |
| Example 82 | R-82 | 27 | 3.3 | 36 |
| Example 83 | R-83 | 26 | 3.3 | 35 |
| Example 84 | R-84 | 26 | 3.2 | 35 |
| Example 85 | R-85 | 26 | 3.2 | 37 |
| Example 86 | R-86 | 27 | 3.2 | 38 |
| Example 87 | R-87 | 27 | 3.2 | 38 |
| Example 88 | R-88 | 26 | 3.3 | 37 |
| Example 89 | R-89 | 28 | 3.3 | 36 |
| Example 90 | R-90 | 27 | 3.2 | 35 |
| Example 91 | R-91 | 25 | 3.2 | 37 |
| Example 92 | R-92 | 25 | 3.1 | 36 |
| Example 93 | R-93 | 27 | 3.1 | 38 |
| Example 94 | R-94 | 28 | 3.1 | 36 |
| Example 95 | R-95 | 26 | 3.2 | 38 |
| Example 96 | R-96 | 25 | 3.1 | 34 |
| Example 97 | R-97 | 25 | 3.1 | 33 |
| Example 98 | R-98 | 24 | 3.1 | 32 |
| Comparative | CR-1 | 27 | 4.4 | 31 |
| Example 1 | | | | |
| Comparative | CR-2 | 27 | 4.3 | 29 |
| Example 2 | | | | |
| Comparative | CR-3 | 26 | 4.4 | 28 |
| Example 3 | | | | |
| Comparative | CR-4 | 28 | 4.1 | 33 |
| Example 4 | | | | |
| Comparative | CR-5 | 27 | 4.1 | 30 |
| Example 5 | | | | |
| Comparative | CR-6 | 27 | 4.0 | 35 |
| Example 6 | | | | |
| Comparative | CR-7 | 42 | 4.7 | 26 |
| Example 7 | | | | |

Obviously, numerous modifications and variations of the present invention(s) are possible in light of the above teachings. It is therefore to be understood that within the scope of the appended claims, the invention(s) may be practiced otherwise than as specifically described herein.

What is claimed is:

1. A radiation-sensitive resin composition comprising:
a polymer, solubility of which in a developer solution is capable of being altered by an action of an acid, and which comprises a first structural unit represented by formula (1);
a radiation-sensitive acid generating agent; and
an acid diffusion control agent comprising a monovalent radiation-sensitive onium cation and a monovalent organic acid anion, 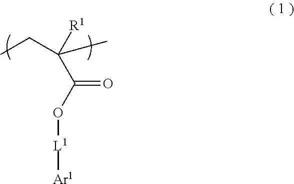
wherein, in the formula (1), R¹ represents a hydrogen atom, a fluorine atom, a methyl group, or a trifluoromethyl group; L¹ represents a single bond or a divalent linking group; and Ar¹ represents a group obtained by removing one hydrogen atom from a substituted or unsubstituted condensed polycyclic aromatic hydrocarbon ring having 13 or more ring atoms.

2. The radiation-sensitive resin composition according to claim 1, wherein the condensed polycyclic aromatic hydrocarbon ring has 13 or more and 22 or fewer ring atoms.

3. The radiation-sensitive resin composition according to claim 1, wherein the condensed polycyclic aromatic hydrocarbon ring is a condensed tricyclic aromatic hydrocarbon ring or a condensed tetracyclic aromatic hydrocarbon ring.

4. The radiation-sensitive resin composition according to claim 1, wherein the condensed polycyclic aromatic hydrocarbon ring is an anthracene ring or a pyrene ring.

5. The radiation-sensitive resin composition according to claim 1, wherein the polymer further comprises a second structural unit comprising an acid-labile group.

6. The radiation-sensitive resin composition according to claim 1, wherein the polymer further comprises a third structural unit comprising a phenolic hydroxyl group.

7. A method of forming a resist pattern, the method comprising:
applying the radiation-sensitive resin composition according to claim 1 directly or indirectly on a substrate to form a resist film;
exposing the resist film; and
developing the resist film exposed.
